(19) United States
(12) Patent Application Publication
(10) Pub. No.: US 2026/0353690 A1
(43) Pub. Date: Nov. 5, 2026

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: CHING-PAI HSU, NEW TAIPEI CITY (TW); TSUNG-YU CHIANG, NEW TAIPEI CITY (TW)

(21) Appl. No.: 19/738,559

(22) Filed: Jul. 13, 2026

Related U.S. Application Data
(63) Continuation of application No. 19/080,972, filed on Mar. 17, 2025.
(60) Provisional application No. 63/710,620, filed on Oct. 23, 2024.

(51) Int. Cl. H10D 30/01; H10D 30/00

(52) U.S. Cl. CPC H10D 30/0195; H10D 30/508

(57) ABSTRACT

A method for forming a semiconductor structure is provided. The method includes alternately stacking channel layers and sacrificial layers on a substrate in a vertical direction to form a semiconductor stack, patterning the semiconductor stack to form a fin-shaped structure protruding from the substrate, forming a source/drain trench in the fin-shaped structure, laterally recessing the sacrificial layers in the fin-shaped structure to form first recesses, and removing portions of the channel layers adjacent to the first recesses to enlarge the first recesses and form second recesses. One of the sacrificial layers includes a middle portion and an outer portion between the middle portion and adjacent channel layers, and a lateral recess amount of the middle portion is greater than that of the outer portion. The method further includes forming inner spacers in the second recesses, and forming a source/drain feature in the source/drain trench.

### CROSS-REFERENCE TO RELATED APPLICATIONS

This application is a Continuation of pending U.S. patent application Serial No. 19/080,972, filed on Mar. 17, 2025, which claims the benefit of U.S. Provisional Application No. 63/710,620, filed Oct. 23, 2024, the entirety of which are incorporated by reference herein.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Recently, multi-gate transistors have been introduced in an effort to improve gate control by increasing gate-channel coupling, reduce OFF-state current and reduce short-channel effects (SCEs). One such multi-gate transistor that has been introduced is the fin field-effect transistor (FinFET). The FinFET gets its name from the fin-shaped structure which extends from a substrate on which it is formed, and which is used to form the FET channel. A further type of multi-gate transistor, introduced in part to address performance challenges associated with some configurations of FinFETs, is a wrap-around gate device, such as a gate-all-around (GAA) transistor. The wrap-around gate device gets its name from the gate structure which extends completely around the channel region, providing access to the channel on four sides. The channels of the wrap-around gate device have a plurality of horizontal nanowires, nanosheets, and/or nano-strips spaced vertically. The wrap-around gate devices are compatible with conventional complementary metal-oxide-semiconductor (CMOS) processes and their structure allows them to be aggressively scaled while maintaining gate control and mitigating SCEs.

In multi-gate devices, such as wrap-around gate devices, inner spacers have been used to reduce capacitance and leakage between gate structures and source/drain features. Although current methods for forming wrap-around gate devices with inner spacers have been generally adequate for their intended purposes, they continue to face challenges in terms of both device fabrication and performance, and are not satisfactory in every respect.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart illustrating a method for forming a semiconductor structure from a workpiece, in accordance with some embodiments of the present disclosure.

FIG. 2 is a fragmentary perspective view of a semiconductor structure at an intermediate stage, in accordance with some embodiments of the present disclosure.

FIGS. 3A, 3B, 3C, 3D, 3E-1, 3E-2, 3E-3, 3E-4, 3F, 3G, 3H, 3I, 3J, 3K, and 3L are fragmentary cross-sectional views illustrating the manufacturing of a semiconductor structure at various intermediate stages, in accordance with some embodiments of the method in FIG. 1.

FIG. 4 illustrates a portion of the semiconductor structure in FIG. 3J, in accordance with some embodiments of the present disclosure.

FIGS. 5A, 5B, 5C, 5D, 5E, 5F, 5G, 5H, 5I, 5J, 5K, and 5L are fragmentary cross-sectional views illustrating the manufacturing of a semiconductor structure at various intermediate stages, in accordance with some embodiments of the present disclosure.

FIG. 6A illustrates a portion of the semiconductor structure in FIG. 3F, in accordance with some embodiments of the present disclosure.

FIG. 6B illustrates a portion of the semiconductor structure in FIG. 5F, in accordance with some embodiments of the present disclosure.

FIG. 7 is a fragmentary cross-sectional view of a semiconductor structure at an intermediate stage, in accordance with some other embodiments of the present disclosure.

FIGS. 8A, 8B, 8C, 8D, 8E, 8F, and 8G are fragmentary cross-sectional views of manufacturing a semiconductor structure at various intermediate stages, in accordance with some embodiments of the present disclosure.

FIG. 9A is a graph depicting a distribution of germanium concentration across the sacrificial layer, in accordance with some embodiments of the present disclosure.

FIG. 9B is another graph depicting a distribution of germanium concentration across the sacrificial layer, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “below,” “lower,” “above,” “upper,” "on" and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as "first," "second" and "third" describe various elements, components, regions, layers and/or sections, but these elements, components, regions, layers and/or sections should not be limited by these terms. These terms may be only used to distinguish one element, component, region, layer or section from another. The terms such as "first," "second" and "third" when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms "substantially," "approximately" or “about” generally mean within a value or range that can be contemplated by people having ordinary skill in the art. Alternatively, the terms "substantially," "approximately" or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the like thereof disclosed herein should be understood as modified in all instances by the terms "substantially," "approximately" or "about." Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure is generally related to multi-gate transistors and fabrication methods, and more particularly to inner spacer formation during fabricating of wrap-around gate (such as GAA) transistors. In a wrap-around gate transistor, the gate of the transistor is made all around the channel such that the channel is surrounded or wrapped by the gate. Such a transistor has the advantage of improving the electrostatic control of the channel by the gate, which also mitigates leakage currents. A wrap-around gate transistor includes inner spacers and outer gate sidewall spacers (or simply referred to as gate spacers). Inner spacers are formed by an additional process to gate spacers. The inner spacers are formed between the channel layers, and used to reduce capacitance and leakage between gate structures and source/drain features. An object of the present disclosure is to devise a method for forming robust inner spacers, thereby preventing undesired leakage paths between the gate structures and the source/drain features. A source/drain feature may refer to a source or a drain, individually or collectively dependent upon the context.

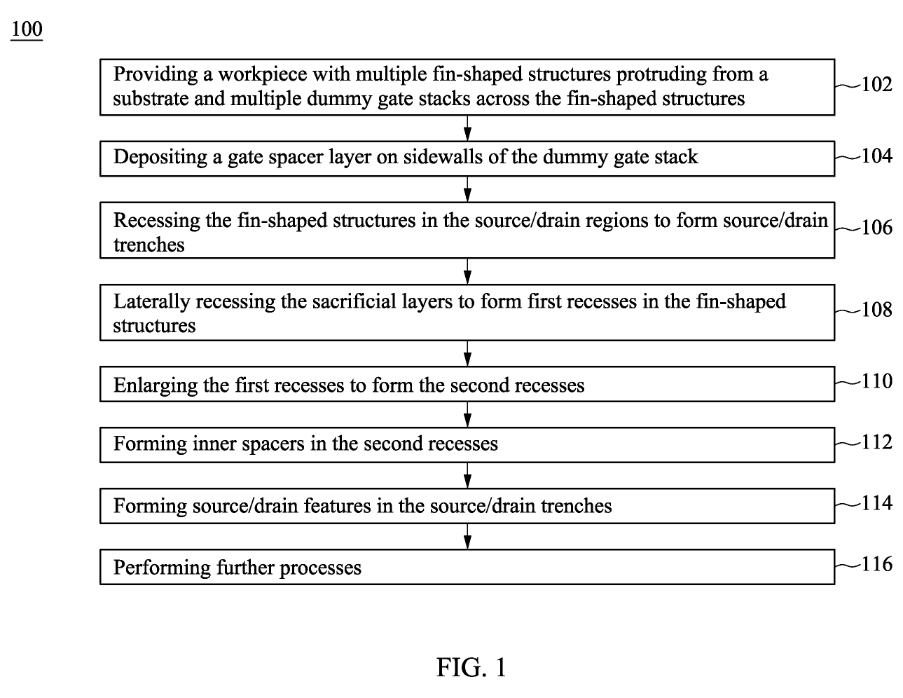

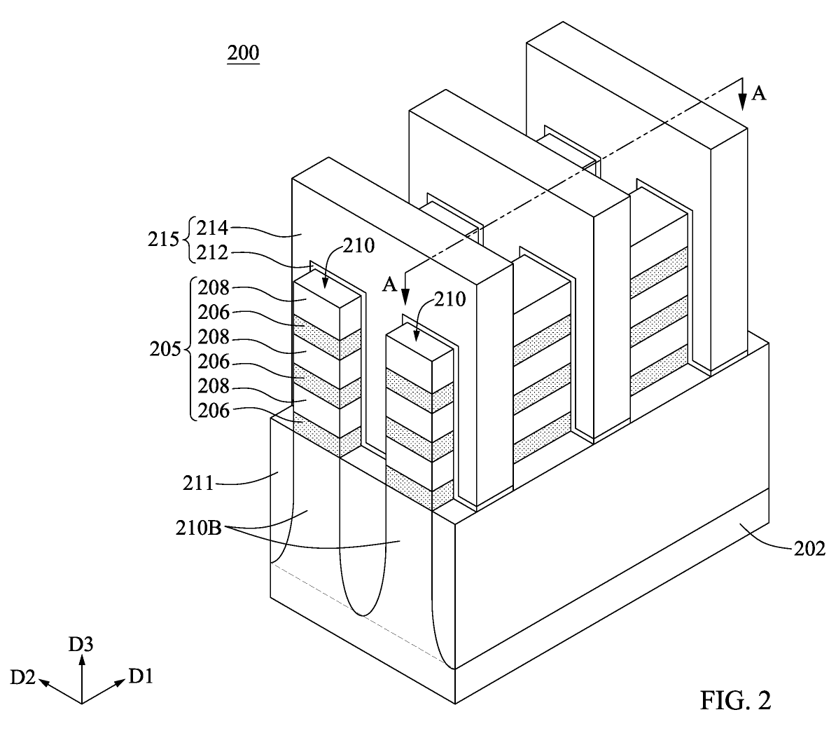

The various aspects of the present disclosure will now be described in more detail with reference to the figures. In that regard, FIG. 1 is a flowchart illustrating a method 100 for forming a semiconductor structure from a workpiece according to an embodiment of the present disclosure. FIG. 2 is a fragmentary perspective view of a semiconductor structure at an intermediate stage, in accordance with some embodiments. A nanosheet field-effect transistor is exemplified to illustrate a semiconductor structure in some embodiments; however, the disclosure is not limited to the nanosheet field-effect transistor.

Method 100 is merely an example and is not intended to limit the present disclosure to what is explicitly illustrated in method 100. Additional steps can be provided before, during, and after method 100, and some steps described can be replaced, eliminated, or rearranged around for additional embodiments of the method. Not all steps are described herein in detail for reasons of simplicity. Method 100 is described below in conjunction with FIG. 2, which is a perspective view of a workpiece 200. Because the workpiece 200 will be fabricated into a semiconductor structure, the workpiece 200 may be referred to herein as a semiconductor structure 200. In addition, the directions D1, D2 and D3 in FIGS. 2, 3A-3L, 4, 5A-5L, 6A, 6B, 7, and 8A-8G are perpendicular to one another. Throughout the present disclosure, like reference numerals denote like features, unless otherwise specified.

In some embodiments, as shown in FIG. 2, the semiconductor structure 200 includes fin-shaped structures 210 protruding from a substrate 202. Each of the fin-shaped structures 210 includes sacrificial layers 206 and channel layers 208 alternately stacked over the substrate 202. Multiple dummy gate stacks 215 extend across the fin-shaped structures 210 and are oriented lengthwise along the direction D2. In some embodiments, the extending direction of the fin-shaped structures 210 is perpendicular to the extending direction of the dummy gate stacks 215. Source/drain regions are formed on opposing sides of the dummy gate stacks 215. The channel layers 208 over the substrate 202 are formed between the source/drain regions. Isolation features 211 are formed on opposing sides of the fin-shaped structures 210. The isolation features 211 may be leveled with the top surfaces of the fin-shaped bases 210B. Each of the dummy gate stacks 215 may include a dummy dielectric layer 212 on the fin-shaped structures 210 and a dummy electrode layer 214 on the dummy dielectric layer 212.

FIG. 2 further illustrates the reference cross-section that is used in later figures. Cross-section A-A is along a longitudinal axis of a fin-shaped structure 210 (e.g., in direction D1), for example, perpendicular to the direction (e.g., direction D2) along a longitudinal axis of a dummy gate stack 215. Subsequent figures refer to the reference cross-section A-A for clarity.

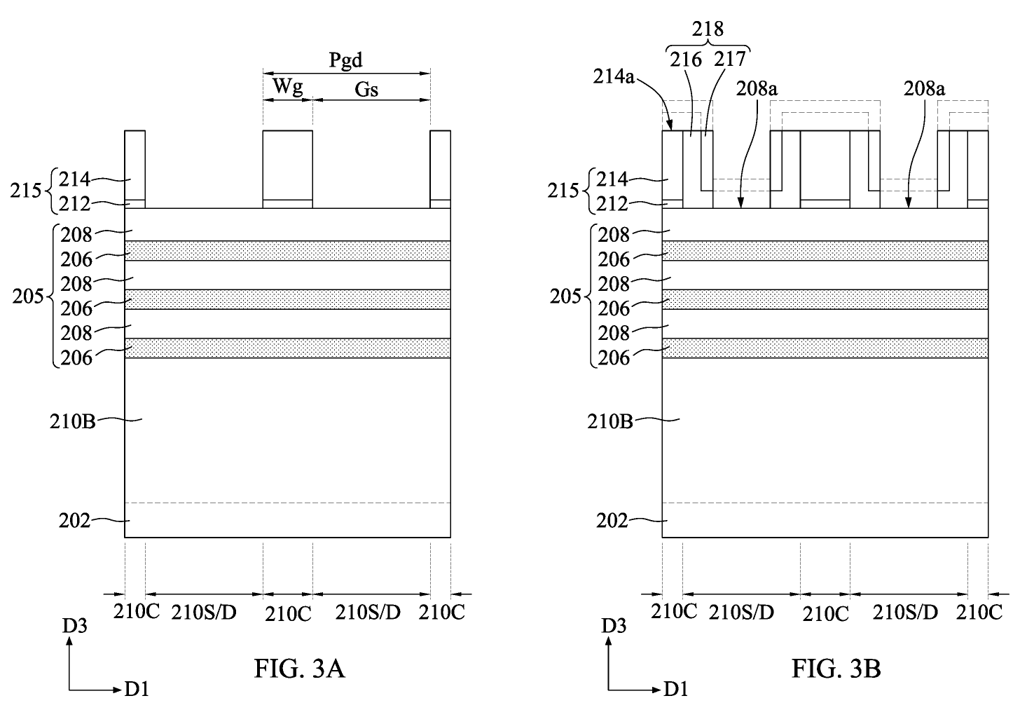

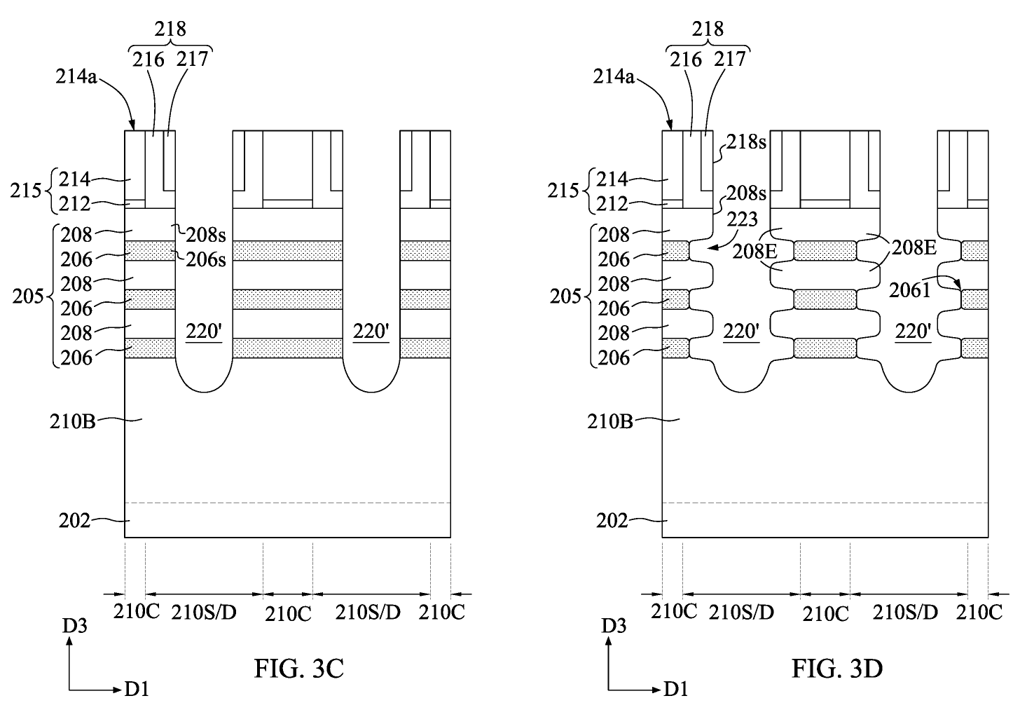

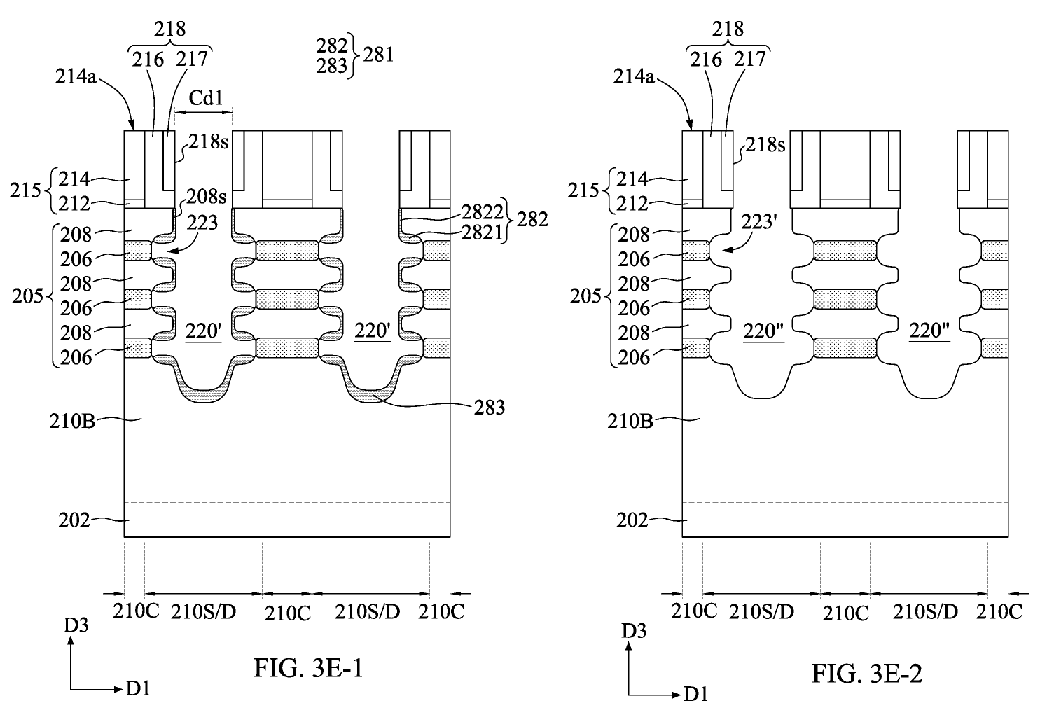

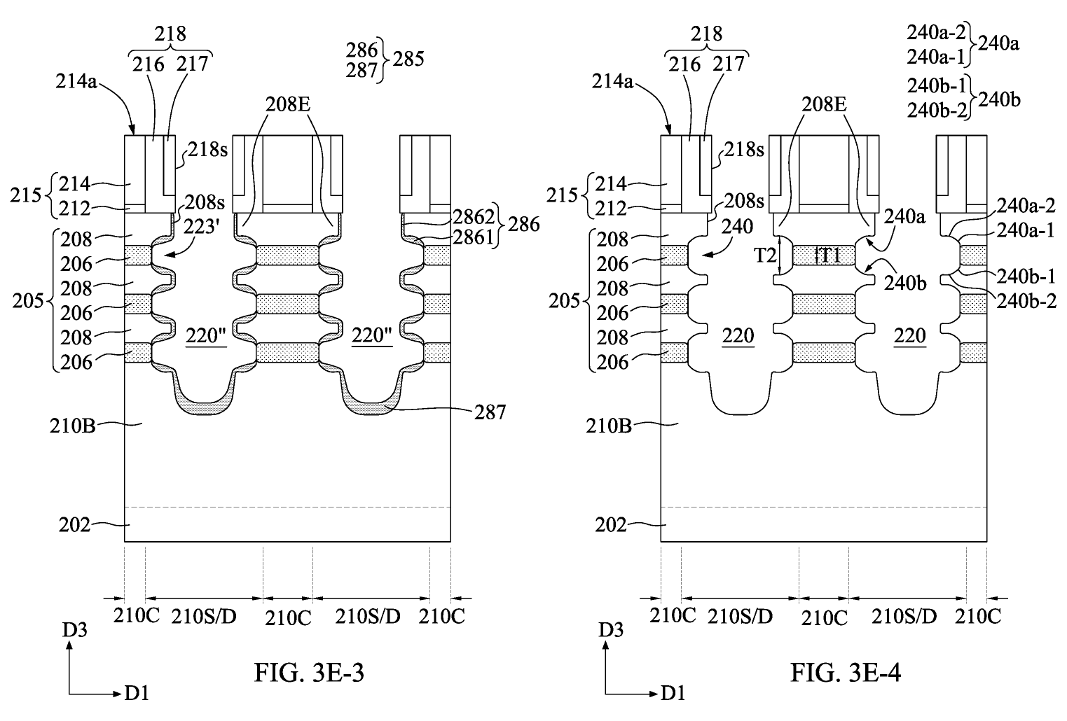

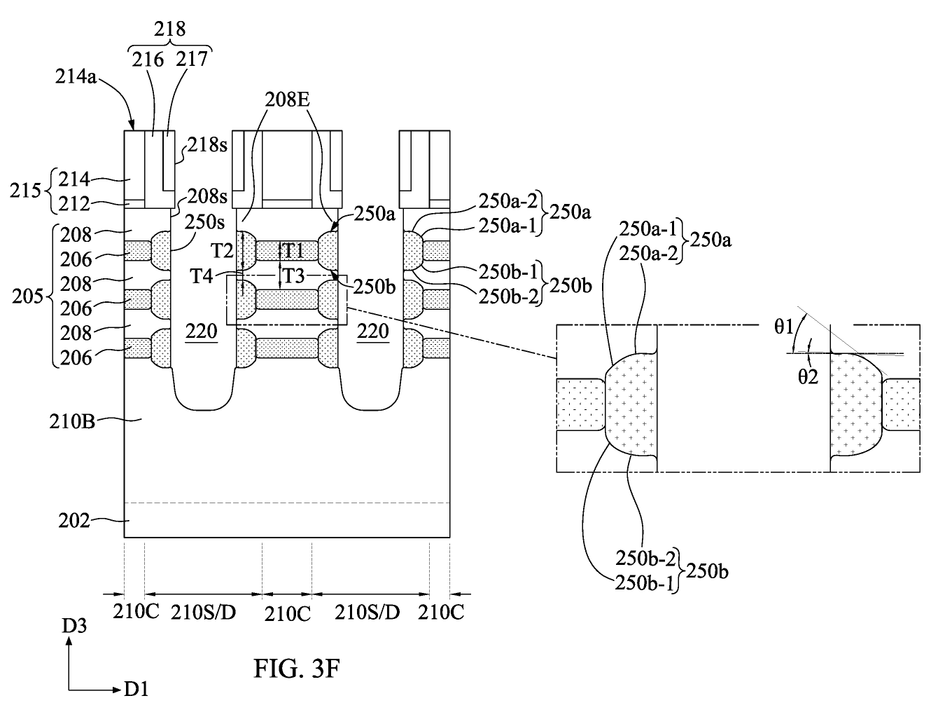

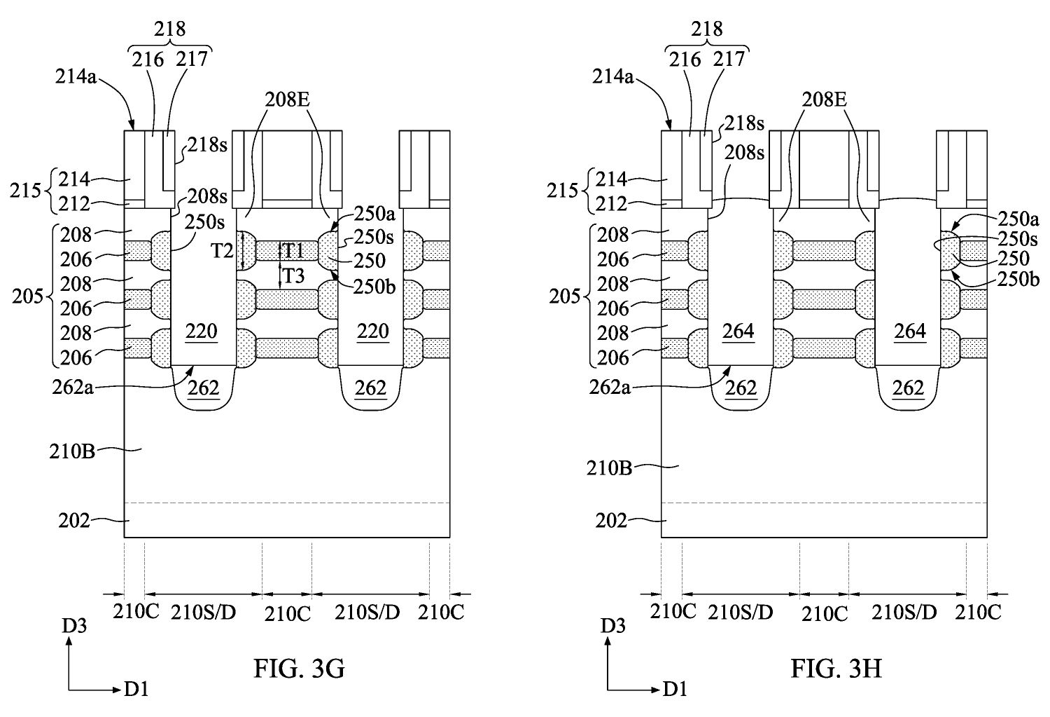

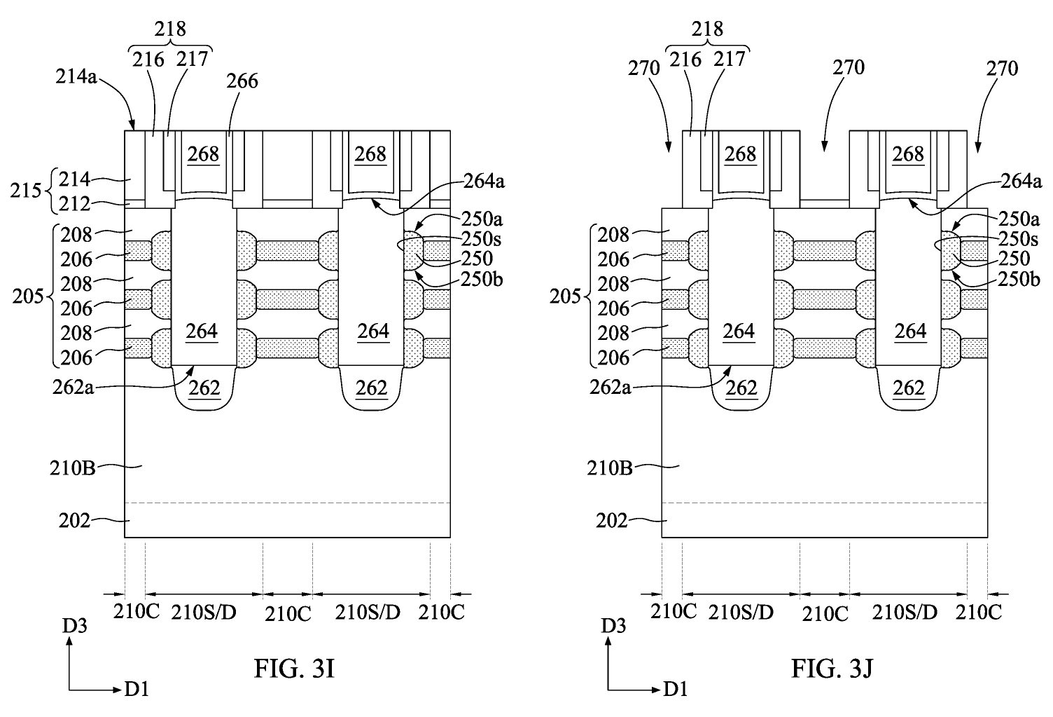

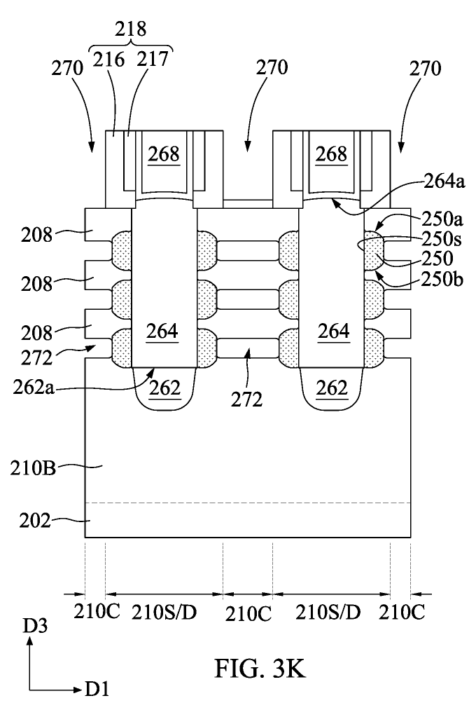

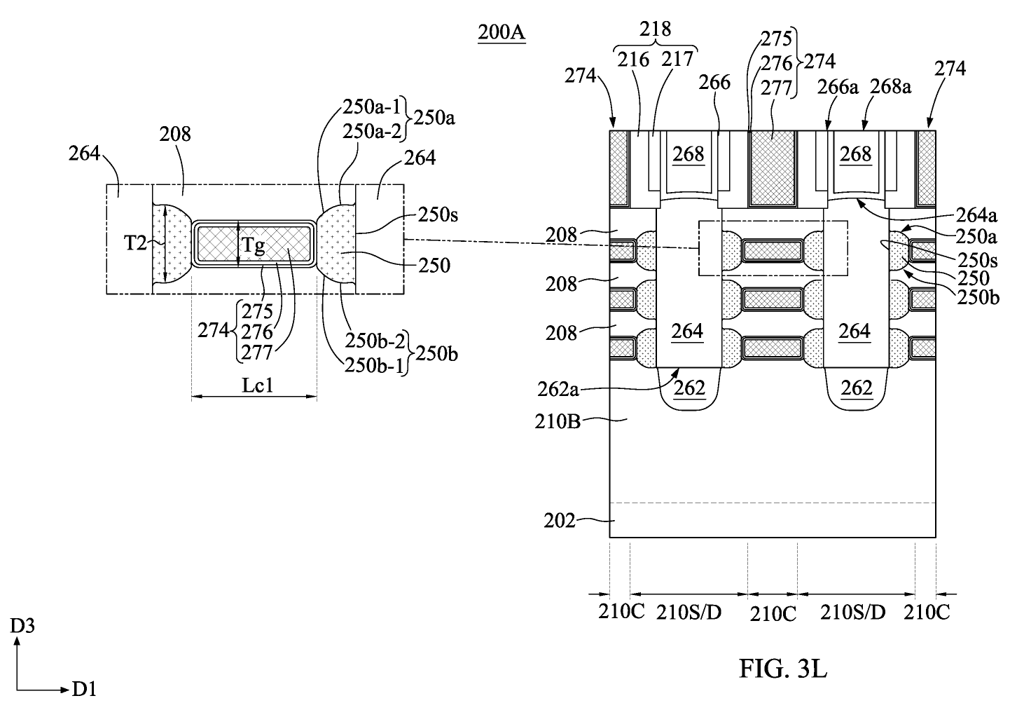

FIGS. 3A-3L are fragmentary cross-sectional views illustrating the manufacturing of a semiconductor structure at various intermediate stages, in accordance with some embodiments of the method 100 in FIG. 1. FIG. 3A is a cross-sectional view taken along cross-section A-A in FIG. 2, which extends along the lengthwise direction of a fin-shaped structure 210. Referring to FIGS. 1, 2, and 3A, method 100 includes a block 102 where a workpiece 200 is provided with multiple fin-shaped structures 210 protruding from a substrate 202, and multiple dummy gate stacks 215 are positioned across the fin-shaped structures 210. In some embodiments, the fin-shaped structures 210 are oriented lengthwise along the direction D1, and the dummy gate stacks 215 are oriented lengthwise along the direction D2. The direction D1 may be perpendicular to the direction D2. The fin-shaped structures 210 may include two fins, one in an n-type region (where n-type transistors will be formed) and the other in a p-type region (wherein p-type transistors will be formed). Alternatively, the fin-shaped structures 210 may include two fins, both located in n-type regions or both in p-type regions.

In some embodiments, the substrate 202 may be a semiconductor substrate such as a silicon (Si) substrate. The substrate 202 may include various doping configurations depending on design requirements as is known in the art. In embodiments where the semiconductor device is p-type, an n-well (not shown) may be formed on the portion of the substrate 202 in the p-type region. In some implementations, the n-type dopant for forming the n-well may include phosphorus (P) or arsenic (As). In embodiments where the semiconductor device is n-type, a p-well may be formed on the portion of the substrate 202 in the n-type region. In some implementations, the p-type dopant for forming the p-well may include boron (B) or gallium (Ga). The suitable doping method may include ion implantation of dopants and/or diffusion processes. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may include an epitaxial layer (epi-layer), may be strained for performance enhancement, may include a silicon-on-insulator (SOI) or a germanium-on-insulator (GeOI) structure, and/or may have other suitable enhancement features.

In some embodiments, each of the fin-shaped structures 210 includes alternating layers atop a fin-shaped base 210B. The formation of the fin-shaped structures 210 may include depositing a lamination (not shown) on the substrate 202 in an epitaxial growth process and patterning the lamination and a top portion of the substrate 202 to form multiple stacks 205. Each of the stacks 205 includes a fin-shaped structure 210. Since the fin-shaped base 210B is formed by patterning a top portion of the substrate 202, the fin-shaped base 210B may still be considered a top part of the substrate 202 as the context requires.

The stack 205 includes sacrificial layers 206 interleaved with channel layers 208. The sacrificial layers 206 and the channel layers 208 include different material compositions. In some embodiments, the sacrificial layers 206 include a semiconductor composition, such as silicon germanium (SiGe) or another suitable semiconductor material. In some embodiments, the sacrificial layers 206 include a dielectric composition, such as oxide or another suitable interposer material, and the sacrificial layers 206 can be referred to as sacrificial dielectric interposers. In some embodiments, the channel layers 208 include semiconductor composition silicon (Si). Although three layers of the sacrificial layers 206 and three layers of the channel layers 208 are alternately arranged in the exemplified embodiment, this is for illustrative purposes only, and is not intended to be limiting beyond what is specifically recited in the claims. It can be appreciated that any number of epitaxial layers (i.e. the sacrificial layers 206 and the channel layers 208) may be formed in the stack 205. The number of layers depends on the desired number of channel members for the semiconductor structure 200. In some embodiments, the number of channel layers 208 is between 1 and 20.

In some embodiments, all of the sacrificial layers 206 may have a substantially uniform thickness between about 3 nm and about 10 nm, and all of the channel layers 208 may have a substantially uniform thickness between about 3 nm and about 15 nm. The thicknesses of the sacrificial layer 206 and the channel layers 208 may be the same or different. As described in more detail below, the channel layers 208 or parts thereof may serve as channel members for a subsequently-formed multi-gate device, and the thickness of the channel layers 208 can be determined based on device performance considerations. In some embodiments, the sacrificial layers 206 in the channel region are eventually removed and serve to define a vertical distance between adjacent channel layers 208 of a subsequently-formed multi-gate device. The thickness of the sacrificial layers 206 is determined based on device performance considerations.

The layers in the stack 205 may be deposited using a molecular beam epitaxy (MBE) process, a vapor phase deposition (VPE) process, and/or another suitable epitaxial growth process. Therefore, the stack 205 is also referred to as the epitaxial stack 205. As stated above, in at least some embodiments, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free. That is, the sacrificial layers 206 and the channel layers 208 may have an extrinsic dopant concentration from approximately 0 cm⁻³ to 1x10¹⁷ cm⁻³. No intentional doping is performed during the epitaxial growth processes for forming the sacrificial layers 206 and the channel layers 208.

In some embodiments, the fin-shaped structures 210 may be patterned from the stack 205 and the substrate 202 using a lithography process and an etch process. The lithography process may include photoresist coating (such as spin-on coating), soft baking, mask aligning, exposure, post-exposure baking, photoresist developing, rinsing, drying (such as spin-drying and/or hard baking), other suitable lithography techniques, and/or combinations thereof. In some embodiments, the etch process may include dry etching (such as reactive ion etching (RIE)), wet etching, and/or another etching method. In some implementations, double-patterning or multi-patterning processes may be used to define fin-shaped structures 210 that have, for example, pitches smaller than what is otherwise obtainable using a single, direct photolithography process. For example, in one embodiment, a material layer (not shown) is formed over the substrate 202 and patterned using a photolithography process. Spacers are formed alongside the patterned material layer using a self-aligned process. The material layer is then removed, and the remaining spacers, or mandrels, may then be used to pattern the fin-shaped structures 210 by etching the stack 205 and a top portion of the substrate 202. In some embodiments, each fin-shaped structure 210 measures between about 6 nm and about 80 nm wide along the direction D2, and a distance between opposing sidewalls of two adjacent fin-shaped structures 210 measures between about 10 nm and about 115 nm along the direction D2.

In addition, the workpiece 200 (or semiconductor structure 200) includes isolation features 211 (FIG. 2) deposited in trenches between opposing sidewalls of two adjacent fin-shaped structures 210. In some embodiments, the isolation features 211 are formed in the trenches to isolate the fin-shaped structures 210 from a neighboring fin-shaped structure. The isolation features 211 may also be referred to as shallow trench isolation (STI) features 211. In some exemplified methods for forming the isolation features 211, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric material, another suitable material, and/or combinations thereof. In various examples, the dielectric layer may be deposited by a chemical vapor deposition (CVD) process, a subatmospheric CVD (SACVD) process, a flowable CVD process, a spin-on coating process, and/or another suitable process. The deposited dielectric material is then thinned and planarized, for example by a chemical mechanical polishing (CMP) process. The planarized dielectric layer is further recessed or pulled back by a dry etching process, a wet etching process, and/or a combination thereof to form the STI features 211. The fin-shaped structures 210 rise above the STI features 211 after recessing the planarized dielectric layer. The recessed top surfaces of the STI features 211 may be leveled with the top surfaces of the fin-shaped bases 210B.

After the fin-shaped structures 210 are defined, multiple dummy gate stacks 215 are formed over the fin-shaped structures 210. The dummy gate stack 215 may include a dummy dielectric layer 212 and a dummy electrode layer 214 on the dummy dielectric layer 212. The formation of the dummy gate stacks 215 may include deposition of layers of the dummy gate stack 215 and patterning of these layers. In some embodiments, a dummy dielectric material, a dummy electrode material, and a gate-top hard mask layer (not shown) may be blanketly deposited over the substrate 202, covering the fin-shaped structures 210 and the isolation features 211. In some embodiments, the dummy dielectric material may be formed on the fin-shaped structures 210 using a CVD process, an atomic layer deposition (ALD) process, an oxygen plasma oxidation process, or another suitable process. The dummy dielectric material may include silicon oxide or another suitable dielectric material. In some embodiments, the dummy electrode material may be deposited over the dummy dielectric material using a CVD process, an ALD process, or another suitable process. The dummy electrode material may include polysilicon. For patterning purposes, the gate-top hard mask layer may be deposited on the dummy electrode material using a CVD process, an ALD process, or another suitable process. The dummy electrode material and the dummy dielectric material may then be patterned to form the dummy gate stacks 215 using the gate-top hard mask layer as a patterning mask. For example, the patterning process may include a lithography process (such as photolithography or e-beam lithography), which may further include photoresist coating (such as spin-on coating), soft baking, mask aligning, exposure, post-exposure baking, photoresist developing, rinsing, drying (such as spin-drying and/or hard baking), another suitable lithography technique, and/or combinations thereof. In some embodiments, the etching process may include dry etching (such as RIE etching), wet etching, and/or another etching method.

The dummy gate stacks 215 are formed over respective channel regions 210C of the fin-shaped structures 210. In some embodiments, a gate replacement process (or gate-last process) is adopted, wherein the dummy gate stacks 215 serve as a placeholder to undergo various processes and are to be removed and replaced by the functional gate structures. At intersections of the fin-shaped structures 210 and the functional gate structures, transistors are formed. In the exemplified embodiment, with the dummy gate stacks 215 formed over the fin-shaped structures 210, the fin-shaped structures 210 are divided into channel regions 210C underlying the dummy gate stacks 215 and source/drain regions 210S/D between the channel regions 210C. As shown in FIG. 3A, a channel region 210C is disposed between two source/drain regions 210S/D along the direction D1. In addition, the dummy gate stacks 215 are separated from each other by a gate spacing GS in the direction D1. The gate width Wg of the dummy gate stack 215 and the pitch Pgd between adjacent dummy gate stacks 215 in the direction D1 are also depicted in FIG. 3A. The dummy gate stacks 215 formed in the channel regions 210C may have a uniform gate width Wg.

Referring to FIGS. 1 and 3B, method 100 includes a block 104 where a gate spacer layer 218 is deposited on sidewalls of the dummy gate stack 215. The gate spacer layer 218 may be a single layer or a multi-layer. In some embodiments, one layer of the gate spacer layer 218 may include silicon carbonitride, silicon oxycarbide, silicon oxycarbonitride, or silicon nitride. The gate spacer layers 218 may be deposited over the dummy gate stacks 215 using processes such as a CVD process, a subatmospheric CVD (SACVD) process, an ALD process, or another suitable process.

In some embodiments, the gate spacer layer 218 includes a first gate spacer 216 and a second gate spacer 217 disposed over the first gate spacer 216, as shown in FIG. 3B. The first gate spacer 216 may include silicon oxynitride and the second gate spacer 217 may include silicon nitride. The formation of the gate spacer layer 218 may include conformal depositions of a first gate spacer material (not shown) and a second gate spacer material (not shown) on the first gate spacer material, followed by patterning of these gate spacer materials. The term “conformally” may be used herein for ease of description of a layer having substantially uniform thickness over various regions. In some embodiments, the patterning process may include removing excess portions of the second gate spacer material and the first gate spacer material that include top portions over the top surfaces 214a of the dummy electrode layers 214 and bottom portions over the topmost channel layer 208. As shown in FIG. 3B, remaining portions of the first gate spacer material and the second gate spacer material may be referred to as the first gate spacer 216 and the second gate spacer 217, respectively. In some embodiments, after the patterning process, the top surfaces 214a of the dummy electrode layers 214 and the top surface 208a of the topmost channel layer 208 are exposed. The gate spacer layers 218 may also be referred to as gate spacers 218.

Referring to FIGS. 1 and 3C, method 100 includes a block 106 where the fin-shaped structures 210 in the source/drain regions 210S/D are recessed to form source/drain trenches 220'. In some embodiments, the source/drain regions 210S/D that are not covered by the dummy gate stack 215 and the gate spacer layer 218 are etched by a dry etch process or another suitable etching process to form the source/drain trenches 220'. For example, the dry etch process may utilize an oxygen-containing gas, a fluorine-containing gas (such as CF₄, SF₆, CH₂F₂, CHF₃, and/or C₂F₆), a chlorine-containing gas (such as Cl₂, CHCl₃, CCl₄, and/or BCl₃), a bromine-containing gas (such as HBr and/or CHBr₃), an iodine-containing gas, another suitable gas, plasmas, and/or combinations thereof. In some embodiments, the fin-shaped structures 210 are recessed to expose the sidewalls 206s of the sacrificial layers 206 and the sidewalls 208s of the channel layers 208. In some implementations, the source/drain trenches 220' extend below the stack 205 into the fin-shaped base 210B.

Referring to FIGS. 1 and 3D, method 100 includes a block 108 where the sacrificial layers 206 are laterally recessed to form first recesses 223 in the fin-shaped structures 210. In some embodiments, operation at block 108 may include selective and partial removal of the sacrificial layers 206 to form the first recesses 223 between adjacent channel layers 208. The first recesses 223 expose opposite ends 208E of the channel layers 208. In some embodiments, the sacrificial layers 206 exposed in the source/drain trenches 220' are selectively and laterally recessed to form the first recesses 223 while the gate spacer layer 218, the exposed portion of the fin-shaped base 210B (the substrate 202) and the channel layers 208 are substantially unetched. As shown in FIG. 3D, the first recesses 223 at opposite ends of each of the sacrificial layers 206 are separated from each other along the first direction D1.

In an embodiment where the channel layers 208 consist essentially of silicon (Si) and the sacrificial layers 206 consist essentially of silicon germanium (SiGe), the selective recess of the sacrificial layers 206 may be performed using a selective wet etch process or a selective dry etch process. In some embodiments, a single etching process is performed to laterally recess the sacrificial layers 206. In some embodiments, the selective and partial recess of the sacrificial layers 206 include a SiGe oxidation process followed by a SiGe oxide removal. In that embodiment, the SiGe oxidation process may include use of ozone. In some other embodiments, the selective dry etching process may include use of one or more fluorine-based etchants, such as fluorine gas or hydrofluorocarbons. The selective wet etching process may include an APM etch (e.g., ammonia hydroxide-hydrogen peroxide-water mixture). In some embodiments, the shapes of the first recesses 223 may not be uniform due to etch capability, and the sacrificial layer 206 may have thinner portions at the ends. For example, a recessed region 2061 may be generated between the first recess 223 and the sacrificial layer 206. If the first recesses 223 are filled with a suitable material to form inner spacers (not shown), the channel layers 208 may be etched through to form undesirable seams above and/or beneath the inner spacer during a channel release process. After a gate replacement is formed, defects of metal extrusion through the undesirable seams may occur, resulting in one or more leakage paths between metal gate and source/drain features.

Referring to FIGS. 1 and 3E-4, method 100 includes a block 110 where the first recesses 223 are enlarged to form the second recesses 240. Operation at block 110 may include selectively etching the channel layers 208 to enlarge the first recesses 223 while the gate spacer layer 218 and the sacrificial layers 206 are substantially unetched. In some embodiments, the exposed ends 208E of the channel layers 208 can be shaped by oxidizing the surface of the channel layers 208 to form an oxide layer, and removing the oxide layer, for example, by one or more etching processes. The oxidizing and removing process may be cyclically repeated to enlarge the first recesses 223 (FIG. 3D) until the second recesses 240 are formed to have a desired shape and dimension.

FIGS. 3E-1, 3E-2, 3E-3, and 3E-4 illustrate enlarged cross-sectional views of the manufacture of the second recesses and S/D trenches at various intermediate stages, in accordance with some other embodiments of the present disclosure. In some embodiments, directional oxidation and selective etching may be adopted to control the reshaping of the first recesses 223 and the source/drain trenches 220'. In some embodiments, the second recesses 240 are formed by cyclic oxidation and removal processes until the second recesses 240 with predetermined shape are obtained. The oxidation process may be directionally controlled and performed by one or more gases in a dry etching chamber or tool, so as to oxidize the exposed surfaces of the channel layers 208 in the selected portions of the target material layers. One exemplary embodiment is described below.

Referring to FIG. 3E-1, the exposed ends 208E of the channel layers 208 and the first recesses 223 are selectively oxidized, for example, by one or more suitable dry etching gases, to form the oxide portions 281. The oxide portions 281 may include the oxide portions 282 grown on the channel layers 208, and the oxide portions 283 grown on the bottoms of the source/drain trenches 220'. The oxidation process may consume portions of the channel layers 208 and the substrate 202. In some embodiments, the oxide portions 282 and 283 include silicon dioxide.

Directional oxidation may be used where parts 2821 of the oxide portions 282, which face the first recesses 223, grow at a higher rate than other parts 2822 of the oxide portions 282 at the sidewalls 208s of the channel layers 208. Accordingly, the amounts of the grown oxide portions 282 can be selectively controlled. For example, the amounts of the parts 2821 of the oxide portions 282 produced inside the first recesses 223 can be controlled to be greater than the amounts of the parts 2822 of the oxide portions 282 produced at the sidewalls 208s by using dry etching gases. Additionally, the formation of the oxide portions 282 and 283 (e.g., collectively referred to as the oxide portions 281) may be performed by rapid thermal oxidation (RTO), radical oxidation, plasma oxidation, any suitable anisotropical oxidation process, or a combination thereof.

Referring to FIG. 3E-2, one or more etching processes are performed to remove the oxide portions 281, thereby shaping the first recesses 223 and the bottoms of the source/drain trenches 220'. For example, the oxide portions 282 are removed to form the recesses 223', and the oxide portions 283 are removed to form the source/drain trenches 220''. In some embodiments, the oxide portions 281 are removed by a wet or dry chemical etch, reactive ion etch, any suitable etch, or a combination thereof. In addition, a cycle that includes one or more dry etching processes and one or more wet etching processes may be continuously repeated to form the recesses 223' and the source/drain trenches 220''.

The oxidation process shown in FIG. 3E-1 may be referred to as a first oxidation process, and the removal process shown in FIG. 3E-2 may be referred to as a first removal process. The first oxidation process and the first removal process can be collectively regarded as a first cyclic operation. After the first cyclic operation is performed (FIG. 3E-2), the vertical dimension of the first recesses 223' is greater than the vertical dimension of the first recesses 223 before the first cyclic operation is performed (FIG. 3D). In some embodiments, one or more etching processes are performed to selectively etch the oxide portions 282 and 283, while the dummy gate stacks 215 and the gate spacer layers 218 remain substantially unetched.

Next, in some embodiments, referring to FIG. 3E-3, another oxidation process is performed on the remaining portions of the ends 208E of the channel layers 208 to form the oxide portions 285. The oxide portions 285 may include the oxide portions 286 grown on the remaining portions of the channel layers 208, and the oxide portions 287 grown on the bottoms of the source/drain trenches 220''. The oxidation process may consume portions of the channel layers 208 and the substrate 202. The oxide portions 286 and 287 may include silicon dioxide.

Directional oxidation may be used such that parts 2861 of the oxide portions 286, which face the first recesses 223', grow at a higher rate than other parts 2862 of the oxide portions 286 at the sidewalls 208s of the channel layers 208. Accordingly, the amounts of the grown oxide portions 286 can be selectively controlled. For example, the amounts of parts 2861 of the oxide portions 286 produced inside the first recesses 223' can be controlled to be greater than the amounts of parts 2862 of the oxide portions 286 produced on the sidewalls 208s by using directional dry etching gases. The formation of the oxide portions 286 and 287 (e.g., collectively referred to as the oxide portions 285) may be performed by rapid thermal oxidation (RTO), radical oxidation, plasma oxidation, any suitable anisotropical oxidation process, or a combination thereof.

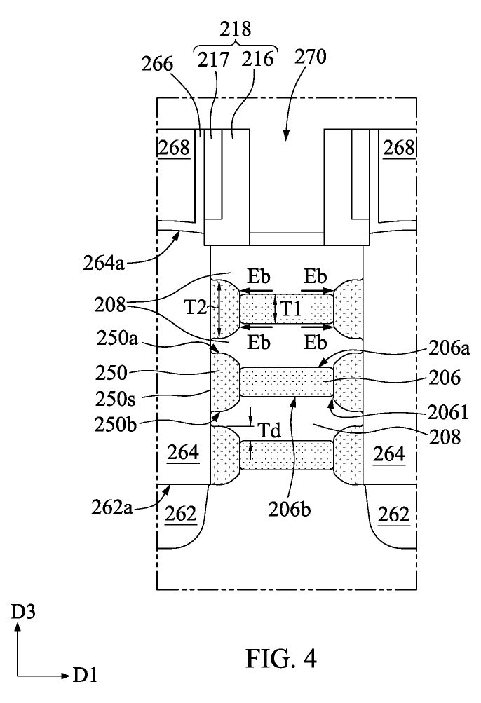

Next, referring to FIG. 3E-4, one or more etching processes are performed to remove the oxide portions 285, thereby shaping the first recesses 223' and the bottoms of the source/drain trenches 220''. In some embodiments, the oxide portions 286 are removed to form the second recesses 240, while the oxide portions 287 are removed to form the source/drain trenches 220. The oxide portions 285 may be removed by, for example, a wet or dry chemical etch, reactive ion etch, any suitable etch, or a combination thereof. In addition, a cycle that includes one or more dry etching processes and one or more wet etching processes may be continuously repeated until the second recesses 240 and the source/drain trenches 220 with desired shapes and dimensions are obtained. After the cyclic operations are performed, the sidewalls 218s of the gate spacers 218 may shield the channel layers 208 from a top view.

The oxidation process shown in FIG. 3E-3 may be referred to as a second oxidation process, and the removal process shown in FIG. 3E-4 may be referred to as a second removal process. The second oxidation process and the second removal process can be collectively regarded as a second cyclic operation. After the second cyclic operation (FIG. 3E-4) is performed, the vertical dimension of the second recesses 240 is greater than the vertical dimension of the first recesses 223' after the first cyclic operation (FIG. 3E-2) has been performed. In some embodiments, one or more etching processes are performed to selectively etch the oxide portions 286 and 287, while the dummy gate stacks 215 and the gate spacer layers 218 remain substantially unetched.

Although two cyclic operations of oxidation and removal processes are provided in this exemplary embodiment, the present disclosure is not limited thereto. The oxidation and removal processes can be cyclically repeated until the second recesses 240 and the source/drain trenches 220 are formed to have desired shapes.

In some embodiments, the first recesses 223 are enlarged to form the second recesses 240, each having a greater vertical dimension than the first recesses 223. As shown in FIG. 3E-4, a maximum vertical dimension T2 of the second recess 240 is greater than the thickness T1 of the sacrificial layer 206. After the inner spacers 250 are subsequently formed in the second recesses 240 (FIG. 3F), the maximum vertical dimension T2 may also be referred to as the thickness T2 of the inner spacer 250 hereinafter for the sake of simplicity in the description.

The second recesses 240 each may have substantially flat top and bottom surfaces, or curved top and bottom surfaces. The cross-sections of the second recesses 240 may be trimmed to have desirable shapes, for example, utilizing the aforementioned exemplary method of cyclical oxidation and removal processes or the like. In some embodiments, the top surface 240a and the bottom surface 240b include curved surfaces, as shown in FIG. 3E-4. One (or each) of the top surfaces 240a of the second recesses 240 may include a first part 240a-1 and a second part 240a-2 that have different curvatures in cross-section. The curvature of the first part 240a-1 may be greater than, equal to or less than the curvature of the second part 240a-2. In some embodiments, the curvature of the first part 240a-1 is greater than the curvature of the second part 240a-2. Similarly, one (or each) of the bottom surfaces 240b of the second recesses 240 may include a first part 240b-1 and a second part 240b-2 that have different curvatures in cross-section. For example, the curvature of the first part 240b-1 may be greater than the curvature of the second part 240b-2 of the bottom surface 240b.

Referring to FIGS. 1 and 3F, method 100 includes a block 112 where inner spacers 250 are formed in the second recesses 240. Operation at block 112 may include deposition of inner spacer material (not shown) over the substrate 202. In some embodiments, the inner spacer material is deposited in the source/drain trenches 220 and fills the second recesses 240. Then, the inner spacer material is etched back to form the inner spacers 250 in the second recesses 240.

One (or each) of the top surfaces 250a and the bottom surfaces 250b of the inner spacers 250 may include curved surfaces with different curvatures or inclined surfaces with different slopes in cross-section. The top surface 250a of the inner spacer 250 may include a first part 250a-1 adjacent to the sacrificial layer 206 (i.e., subsequently replaced by the gate structure 274 as shown in FIG. 3L) and a second part 250a-2 adjacent to the source/drain trenches 220. In some embodiments, the first part 250a-1 and the second part 250a-2 have different curvatures in cross-section. For example, the curvature of the first part 250a-1 may be greater than the curvature of the second part 250a-2 of the top surface 250a. Similarly, the bottom surface 250b of the inner spacer 250 may include a first part 250b-1 and a second part 250b-2, wherein the curvature of the first part 250b-1 may be greater than the curvature of the second part 250b-2. In some embodiments, the first part 250a-1 and the second part 250a-2 of the top surface 250a are inclined with different angles. The first part 250b-1 and the second part 250b-2 of the bottom surface 250b are inclined with different angles. The first part 250a-1 (or 250b-1) may be more slanted relative to a horizontal plane (i.e., D1-D2 plane that the channel layers 208 extend along) than the second part 250a-2 (or 250b-2). For example, as shown in FIG. 3F, an angle θ1 between the first part 250a-1 and the direction D1 is greater than an angle θ2 between the second part 250a-2 and the direction D1.

In some embodiments, after the second recesses 240 and the inner spacers 250 are formed, the inner spacers 250 on opposite sides of the sacrificial layer 206 are thicker than the sacrificial layer 206. As shown in FIG. 3F, the thickness T2 of the inner spacer 250 is greater than the thickness T1 of the sacrificial layer 206. In addition, after the second recesses 240 and the inner spacers 250 are formed, the remaining portions (also denoted as 208) of the channel layers each have different thicknesses. As shown in FIG. 3F, the portion of the channel layers 208 between the sacrificial layers 206 has a thickness T3. The opposite ends 208E of the channel layers 208, between the inner spacers 250, each have a thickness T4. The thickness T4 is less than the thickness T3.

The inner spacer material may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material may be a single layer or a multilayer. In some implementations, the inner spacer material may be deposited using CVD, PECVD, SACVD, ALD, or another suitable method.

In some embodiments, the inner spacer material is deposited into the second recesses 240 as well as over the sidewalls 218s of the gate spacers 218 and the sidewalls 208s of the channel layers 208 exposed in the source/drain trenches 220. The deposited inner spacer material is then etched back to remove the inner spacer material from the sidewalls 208s of the channel layers 208 and the sidewalls 218s of the gate spacers 218, thereby forming the inner spacers 250 in the second recesses 240.

In some implementations, the etch back operations may include use of hydrogen fluoride (HF), fluorine gas (F₂), hydrogen (H₂), ammonia (NH₃), nitrogen trifluoride (NF₃), or another fluorine-based etchant. In some implementations, each of the inner spacers 250 is in contact (e.g., direct contact) with the recessed sacrificial layer 206 and is disposed between two neighboring channel layers 208. In some embodiments, each of the inner spacers 250 has a sidewall 250s that is substantially flush with the sidewalls 208s of the channel layers 208. In the exemplified embodiment, the sidewalls 250s of the inner spacers 250 are not flush with the sidewall 218s of the gate spacer 218. Alternatively, the sidewalls 250s of the inner spacers 250 may be concave (i.e., bending inward toward the respective sacrificial layers 206 adjacent to the inner spacers 250) or convex (i.e., bending outward toward the respective source/drain trench 220).

According to the embodiments, the length of the sacrificial layer 206 along the direction D1 (i.e., the distance between the inner spacers 250 at two opposite ends of the sacrificial layer 206) is a channel length (denoted as Lc1 in FIG. 3L) of a gate structure 274 subsequently formed in a replacement gate process. Therefore, the formation of the second recesses 240 by enlarging the vertical dimension of the first recesses 223 ensures the semiconductor structure has a sufficient channel length.

Referring to FIGS. 1, 3 and 3H, method 100 includes a block 114 where source/drain features 264 are formed in the source/drain trenches 220. Operation at block 114 may include suitable epitaxial processes for growing base epitaxial layers 262 and the source/drain features 264 over the base epitaxial layers 262, which will be described in more detail below.

Referring to FIG. 3G, in some embodiments, after the inner spacers 250 are formed at opposite ends of the sacrificial layers 206, a base epitaxial layer 262 is deposited in the bottom of each of the source/drain trenches 220. Formation of the base epitaxial layers 262 reduces the depth of the source/drain trenches 220 and facilitates the growth of the source/drain features 264 in the subsequent process.

In some embodiments, the base epitaxial layer 262 includes the same material as the substrate 202 and the channel layers 208, such as silicon (Si), except for a dopant condition (doping element and/or doping concentration). For example, the base epitaxial layer 262 is made of non-doped silicon, the substrate 202 is made of doped silicon, and the channel layers 208 are made of non-doped or doped silicon. In some embodiments, the base epitaxial layer 262 includes the same material as the sacrificial layers 206, such as silicon germanium (SiGe), but with different germanium (Ge) contents. In some other embodiments, the base epitaxial layer 262, the channel layers 208, and the sacrificial layers 206 are made of different semiconductor materials. In various embodiments, the base epitaxial layer 262 is dopant-free, where for example, no intentional doping is performed during the epitaxial growth process. As a comparison, the substrate 202 may be lightly doped and has a higher doping concentration than the base epitaxial layer 262.

In addition, the base epitaxial layer 262 provides a high resistance path from the source/drain regions to the substrate 202, such that the leakage current in the substrate 202 (i.e., through the fin-shaped base 210B) is suppressed. The inner spacers 250 limit the vertical growth of the base epitaxial layer 262, as the epitaxial growth may not take place from a dielectric surface. The base epitaxial layer 262 may exhibit faceted growth when it reaches the bottommost inner spacers 250. Thus, in some embodiments, the base epitaxial layer 262 may partially overlap with a bottom portion of the bottommost inner spacers 250 but does not grow vertically beyond the top surface of the bottommost inner spacers 250. The top surface 262a of the base epitaxial layer 262, level with the bottom surface of the bottommost inner spacers 250, is depicted in the drawings for the sake of simplicity and clarity.

Suitable epitaxial processes for growing the base epitaxial layer 262 may include vapor-phase epitaxy (VPE), molecular beam epitaxy (MBE), selective CVD, and/or another suitable process. Various deposition parameters can be tuned to selectively deposit the semiconductor material on exposed semiconductor surfaces in the source/drain trenches 220, such as deposition gas composition, carrier gas composition, deposition gas flow rate, carrier gas flow rate, deposition time, deposition pressure, deposition temperature, source power, RF bias voltage, DC bias voltage, RF bias power, DC bias power, other suitable deposition parameters, or combinations thereof. In some embodiments, the structure is exposed to a deposition mixture that includes DCS and/or SiH₄ (silicon-containing precursor), H₂ (carrier precursor), and HCl (etchant-containing precursor) when forming the base epitaxial layer 262. In some embodiments, the selective CVD process implements a deposition temperature of about 600 °C to about 750 °C. In some embodiments, the selective CVD process implements a deposition pressure of about 10 Torr to about 100 Torr. In some embodiments, a bottom-up deposition process is performed, such that the base epitaxial layer 262 grows from the exposed semiconductor surface at the bottom of the source/drain trench 220, but not from exposed end portions of the channel layers 208. In some embodiments, a post-deposition etch is performed after the selective CVD process to remove any semiconductor material of the base epitaxial layer 262 that may remain on the end portions of the channel layers 208, if any. The post-deposition etch includes a dry etching, a wet etching, other suitable etching process, or combinations thereof.

Referring to FIG. 3H, in some embodiments, the source/drain features 264 are formed in the source/drain trenches 220. In some embodiments, the source/drain features 264 may also be referred to as doped epitaxial layers 264. Sometimes, the term “source/drain features” includes the doped epitaxial layer 264 and the base epitaxial layer 262 underneath.

In an embodiment, forming the source/drain features 264 includes epitaxially growing the semiconductor layers using an MBE process, a chemical vapor deposition process, and/or other suitable epitaxial growth processes. The source/drain features 264 may include silicon doped with phosphorous or arsenic for n-type transistors. The source/drain features 264 may include silicon germanium doped with boron for p-type transistors. The source/drain features 264 cover the base epitaxial layers 262 and are in contact with the inner spacers 250. In addition, the source/drain features 264 are in contact with the sidewalls 208s of the channel layers 208. In some embodiments, the source/drain features 264 grow vertically beyond the top surfaces of the topmost inner spacers 250 and the topmost channel layer 208.

Next, referring to FIGS. 1, 31, 3I, 3J, 3K and 3L, method 100 includes a block 116 where further processes are performed. Such further processes may include, for example, deposition of a contact etch stop layer (CESL) 266 over the structure, deposition of an interlayer dielectric (ILD) layer 268 over the CESL 266 (shown in FIG. 3I), removal of the dummy gate stacks 215 (shown in FIG. 3J), selective removal of the sacrificial layers 206 in the channel regions to release the channel layers 208 as channel members (shown in FIG. 3K), and formation of gate structures 274 over the channel regions (shown in FIG. 3L). Those components, materials and manufacturing methods in some exemplified embodiments will be described in more detail below.

In some embodiments, the CESL 266 is formed prior to forming the ILD layer 268. The CESL 266 may include silicon nitride, silicon oxynitride, and/or another material known in the art. The CESL 266 may be formed by an ALD process, a plasma-enhanced chemical vapor deposition (PECVD) process and/or another suitable deposition process. As shown in FIG. 3I, the CESL 266 is formed on the top surface 264a of the source/drain feature 264.

The ILD layer 268 is then deposited over the CESL 266. In some embodiments, the thickness of the CESL 266 along the first direction D1 is less than the thickness of the ILD layer 268. In addition, the source/drain feature that includes the doped epitaxial layer 264 and the base epitaxial layer 262 underneath is partially embedded in the substrate 202 and beneath the ILD layer 268. The ILD layer 268 may include materials such as tetraethylorthosilicate (TEOS) oxide, undoped silicate glass, or doped silicon oxide such as borophosphosilicate glass (BPSG), fused silica glass (FSG), phosphosilicate glass (PSG), boron-doped silicon glass (BSG), and/or another suitable dielectric material. In some embodiments, the dielectric constant of the ILD layer 268 is less than the dielectric constant of the CESL 266. The ILD layer 268 may be deposited by a PECVD process or another suitable deposition technique. In some embodiments, after formation of the ILD layer 268, the structure may be annealed to improve the integrity of the ILD layer 268. After the deposition of the CESL 266 and the ILD layer 268, a planarization process is performed on the ILD layer 268 and the CESL 266 to remove excess portions over the top surfaces of the dummy gate stacks 215, thereby exposing the dummy gate stacks 215. The planarization process may include a chemical mechanical planarization (CMP) process. Exposure of the dummy gate stacks 215 allows the removal of the dummy gate stacks 215 and release of the channel layers 208.

In some embodiments, as shown in FIG. 3J, the exposed dummy gate stacks 215 are removed to form gate trenches 270 over the channel layers 208. The removal of the dummy gate stacks 215 may include one or more etching processes that are selective to the material of the dummy gate stack 215. For example, the removal of the dummy gate stacks 215 may be performed using a selective wet etch, a selective dry etch, or a combination thereof that is selective to the dummy gate stacks 215. After the removal of the dummy gate stacks 215, the sidewalls of the channel layers 208 and the sacrificial layers 206 in the channel region are exposed in the gate trenches 270.

In some embodiments, as shown in FIG. 3K, after the removal of the dummy gate stacks 215, the method 100 may include an operation to selectively remove the sacrificial layers 206 between the channel layers 208. The selective removal of the sacrificial layers 206 releases the channel layers 208 to form channel members (also numbered as 208). In addition, the selective removal of the sacrificial layers 206 leaves behind space 272 between the channel members 208. The selective removal of the sacrificial layers 206 may be implemented by selective dry etch, selective wet etch, or another selective etch process. The selective dry etching process may include use of one or more fluorine-based etchants, such as fluorine gas or hydrofluorocarbons. The selective wet etching process may include an APM etch (e.g., ammonia hydroxide-hydrogen peroxide-water mixture).

In some embodiments, as shown in FIG. 3L, the method 100 may include further operations to form a gate structure 274 to wrap around each of the channel members 208. In some embodiments, the gate structure 274 is formed within the gate trench 270 and into the space 272 left behind by the removal of the sacrificial layers 206. According to the embodiments, one or each of the inner spacers 250 has the thickness T2 greater than the thickness Tg of the portion of the gate structure 274 between two adjacent channel members 208.

In some embodiments, the gate structure 274 includes a gate dielectric layer 275 and a gate electrode layer 277 over the gate dielectric layer 275. While not explicitly shown in the figures, the gate dielectric layer 275 may include an interfacial layer and a high-K gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or another suitable method.

High-K dielectric materials for forming the gate dielectric layer 275 may include dielectric materials having a high dielectric constant greater than that of thermal silicon oxide (about 3.9). The high-K gate dielectric layer may include hafnium oxide, titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or another suitable method. In one embodiment, the gate dielectric layer 275 is formed using a highly conformal deposition process such as ALD in order to ensure the formation of a gate dielectric layer having a uniform thickness around each channel layer 208.

The gate electrode layer 277 of the gate structure 274 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, and/or combinations thereof. The gate electrode layer 277 may be formed by ALD, PVD, CVD, e-beam evaporation, or another suitable process. In some embodiments, a gate dielectric material layer and a gate electrode material layer are deposited over the top surface 266a of the CESL 266 and the top surface 268a of the ILD layer 268. Excessive amounts of the gate dielectric material layer and the gate electrode material layer formed over the ILD layer 268 are then planarized using, for example, a CMP process, until the CESL 266 and the ILD layer 268 are exposed. Thus, the gate structure 274 may provide a substantially planar top surface. In addition, the gate structure 274 includes portions that interpose between the channel members 208 in the channel region.

In some embodiments, the gate structure 274 further includes a work function adjustment layer 276 disposed between the gate dielectric layer 275 and the gate electrode layer 277 to enhance the device performance. The work function adjustment layer 276 may include one or more work function metal layers. In some embodiments, the work function adjustment layer 276 is made of one or more conductive materials, such as a single layer of TiN, TaN, TaAlC, TiC, TaC, Co, Al, TiAl, HfTi, TiSi, TaSi, or TiAlC, or a multilayer of two or more of these materials. The work function adjustment layer 276 may be formed by ALD, PVD, CVD, e-beam evaporation, or another suitable process.

According to the semiconductor structure 200A of some embodiments, the inner spacers 250 each have an enlarged vertical dimension that effectively prevents the formation of cracks that typically occur during removal of the sacrificial layers 206, thereby solving the conventional problem of metal extrusion through the cracks for forming the leakage paths after a replacement gate is formed.

FIG. 4 illustrates a portion of the semiconductor structure in FIG. 3J, in accordance with some embodiments of the present disclosure.

As shown in FIG. 4, in some embodiments, the thickness T2 of the inner spacer 250 is greater than the thickness T1 of the sacrificial layer 206. For example, the top surface 206a of the sacrificial layer 206 is substantially positioned at a lower horizontal level than the top surface 250a of the inner spacer 250. The bottom surface 206b of the sacrificial layer 206 is substantially positioned at a higher horizontal level than the bottom surface 250b of the inner spacer 250. When the sacrificial layers 206 have thinner ends and a recessed region 2061 is generated between the inner spacer 250 and the sacrificial layer 206, the inner spacers 250 function as solid barrier walls to stop the lateral etch (e.g., as depicted by the arrows Eb) effectively during the selective removal of the sacrificial layers 206, thereby preventing formation of the leakage paths after a replacement gate is formed.

In some (but not limited) embodiments, the thickness T1 of the sacrificial layer 206 is in a range of about 8.5 nm to 10.5 nm, and the difference Td between the top surface 250a (e.g., the second part 250a-2) of the inner spacer 250 and the top surface 206a of the sacrificial layer 206 is in a range of about 0.5 nm to 1.5 nm. In some (but not limited) embodiments, the difference Td is in a range of about 4.5% to 20% of the thickness T2. In some (but not limited) embodiments, the difference Td is in a range of about 5% to 15% of the thickness T2. Those numerical values are provided for exemplification purposees only and are not intended to be limiting.

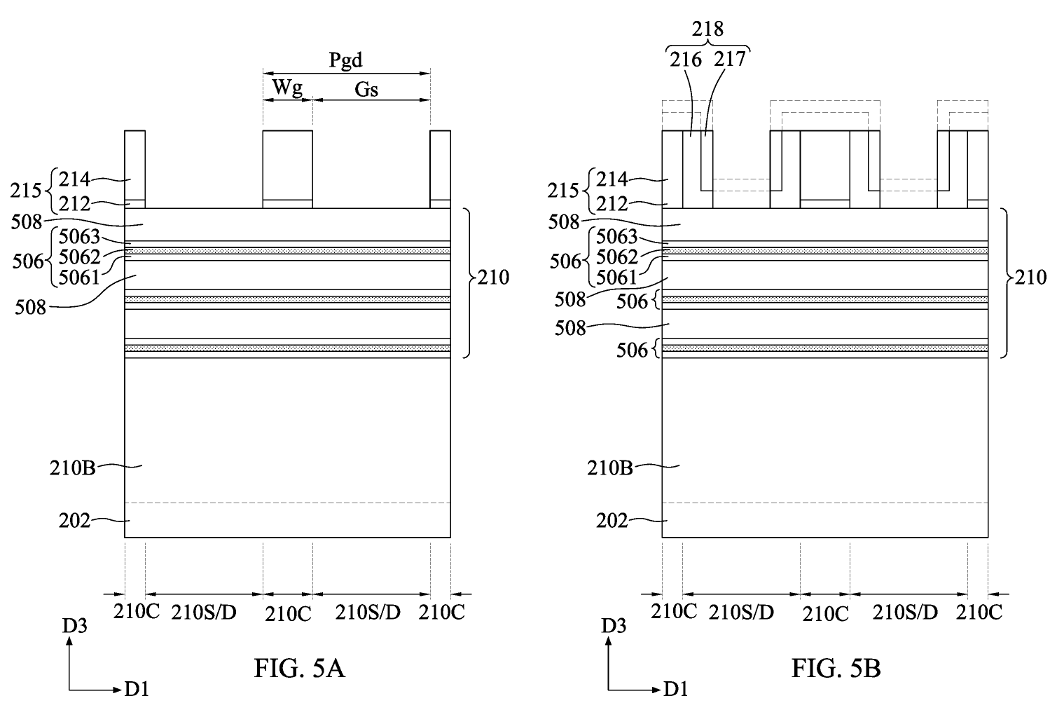

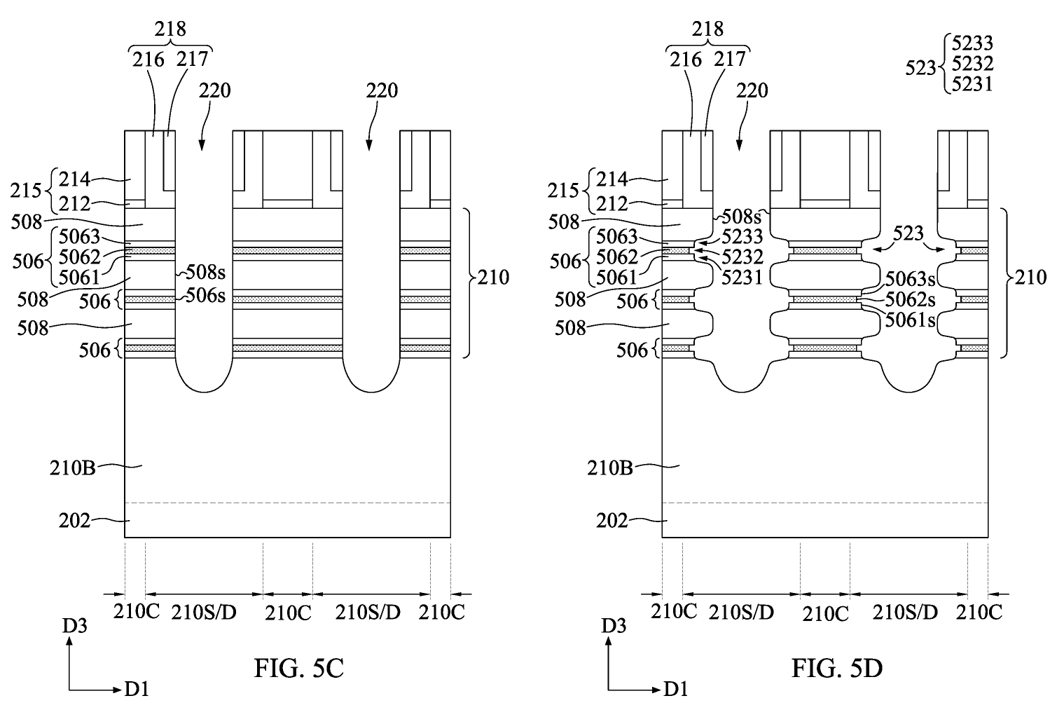

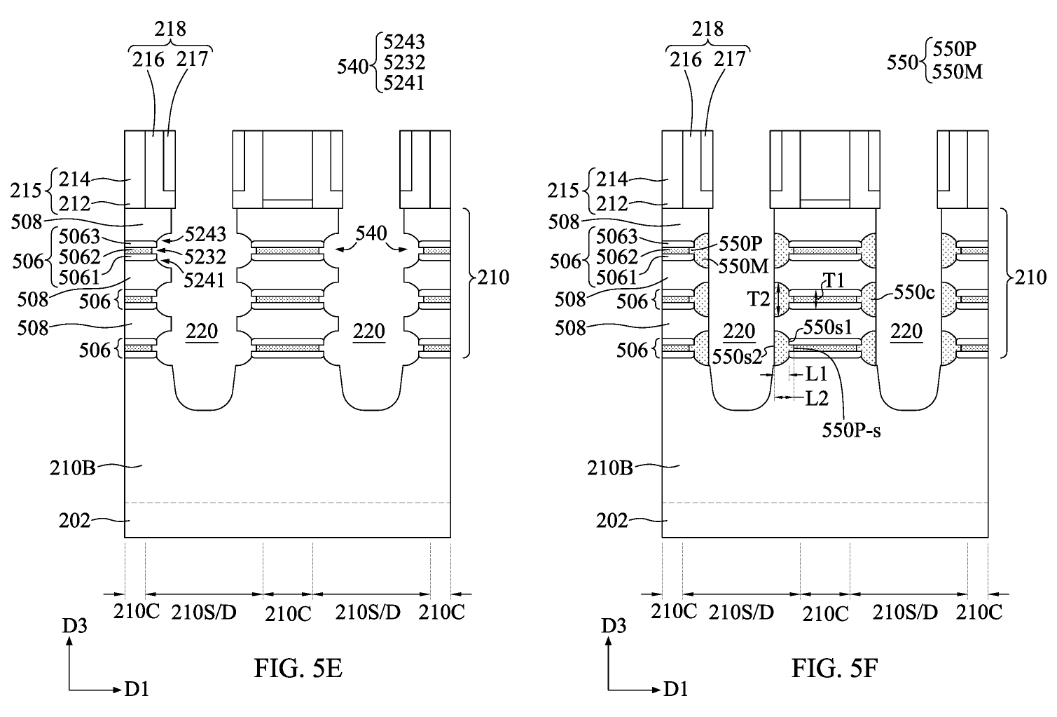

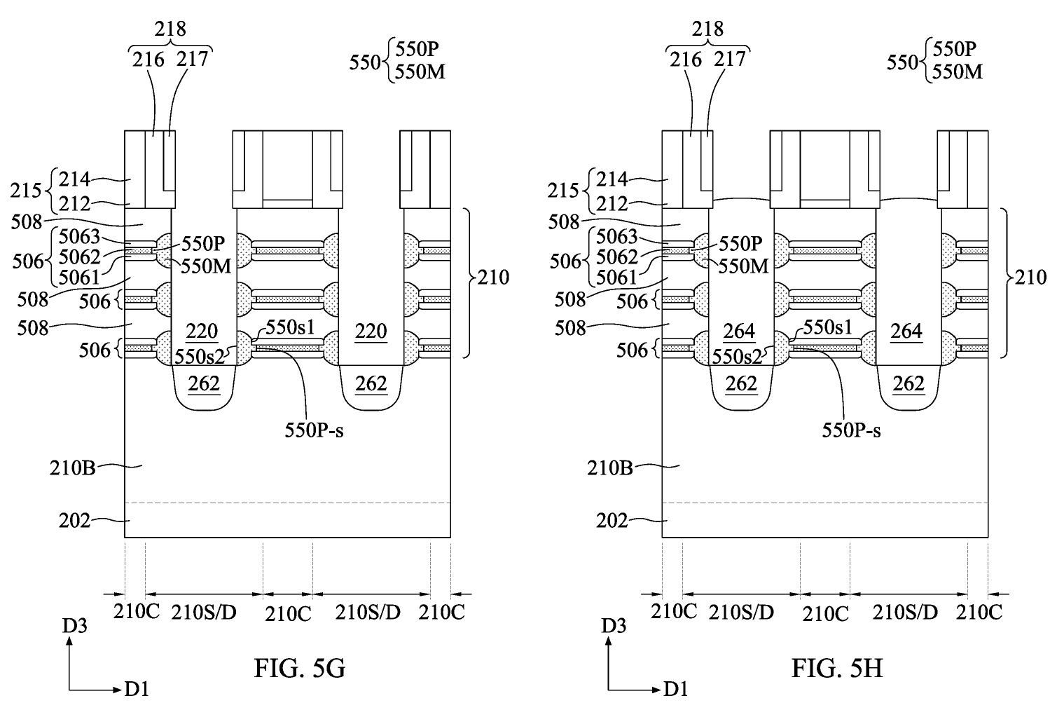

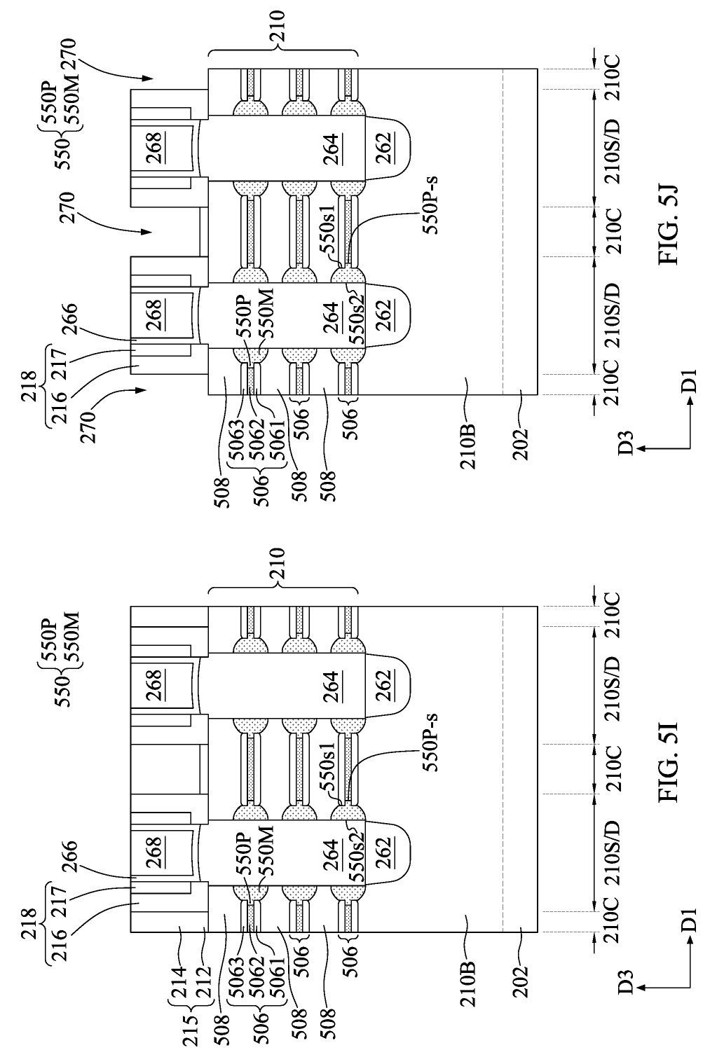

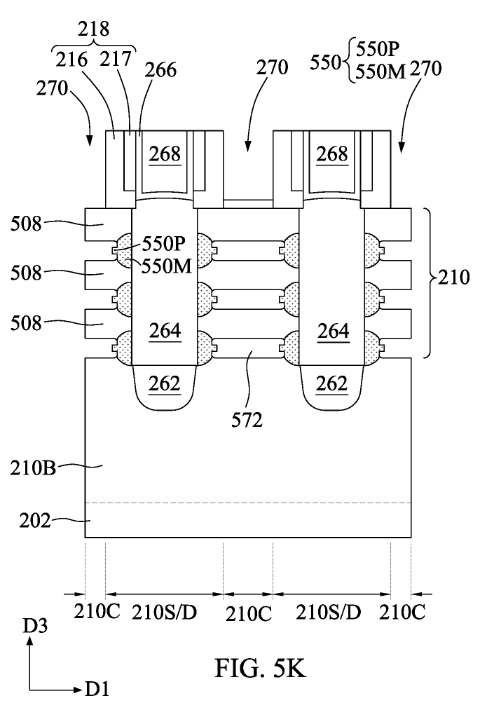

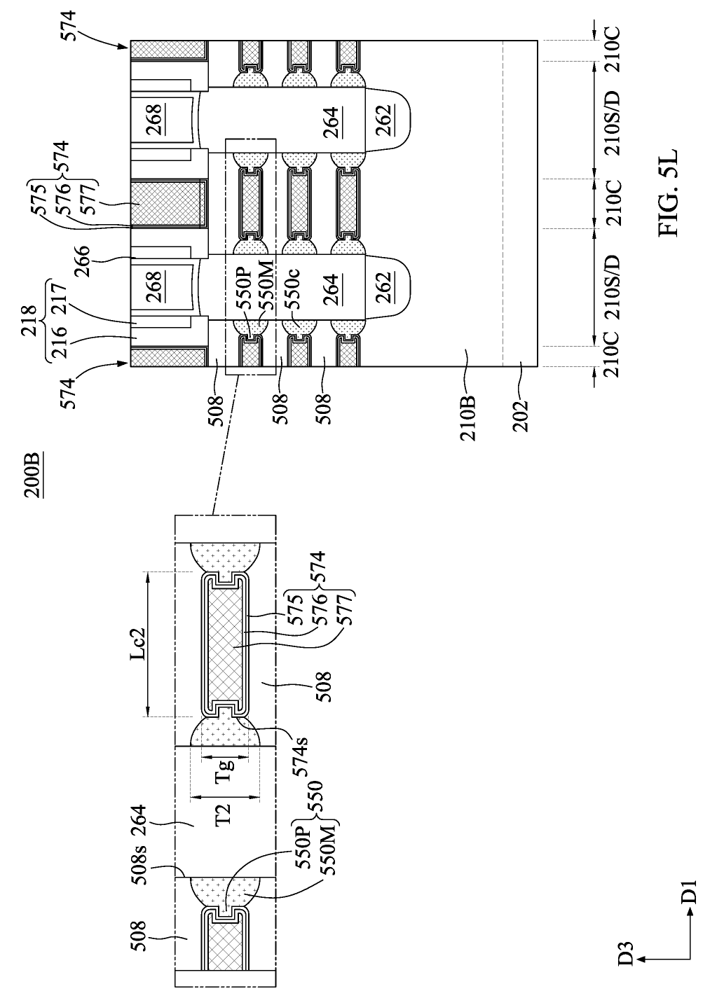

FIGS. 5A-5L are fragmentary cross-sectional views illustrating the manufacturing of a semiconductor structure at various intermediate stages, in accordance with some embodiments of the present disclosure. The features/components in FIGS. 5A-5L that are similar or identical to the features/components in FIGS. 3A-3L are designated with similar or the same reference numbers. Details of the arrangement, materials, and manufacturing methods of those similar or identical features/components shown in FIGS. 5A-5L are essentially the same as those discussed with reference to FIGS. 3A-3L, and are not repeated herein.

According to an aspect of some embodiments, a method for forming a semiconductor structure 200B in FIG. 5L is similar to the method for forming the semiconductor structure 200A in FIG. 3L, except that each of the sacrificial layers 506 in FIGS. 5A-5J is a stack of films, wherein a lateral recess amount of the middle film of the stack is different from that of the other films of the stack.

Referring to FIGS. 2 and 5A, in some embodiments, multiple fin-shaped structures 210 protruding from the substrate 202 are provided, and multiple dummy gate stacks 215 across the fin-shaped structures 210 are formed. Each of the fin-shaped structures 210 includes alternating layers atop a fin-shaped base 210B. The formation of the fin-shaped structures 210 may include depositing a lamination (not shown) on the substrate 202 in an epitaxial growth process. The lamination and a top portion of the substrate 202 are patterned to form multiple stacks 205. Each of the stacks 205 includes a fin-shaped structure 210, which includes sacrificial layers 506 interleaved with channel layers 508.

In some embodiments, each of the sacrificial layers 506 includes a sacrificial middle film 5062 disposed between two sacrificial outer films 5061 and 5063. The sacrificial middle film 5062 and the sacrificial outer films 5061 and 5063 include different semiconductor compositions so that the sacrificial middle film 5062 and the sacrificial outer films 5061 and 5063 have different etch rates. In addition, in some embodiments, the thicknesses of the sacrificial middle film 5062 and the sacrificial outer films 5061 and 5063 are substantially the same. In some embodiments, the sacrificial middle film 5062 is thicker than one of the sacrificial outer films 5061 and 5063. In some embodiments, the sacrificial middle film 5062 is thinner than one of the sacrificial outer films 5061 and 5063.

In some embodiments, the sacrificial layers 506 include silicon germanium (SiGe), and a germanium concentration of the sacrificial middle film 5062 is greater than a germanium concentration of the sacrificial outer films 5061 and 5063. In some (but not limited) examples, the germanium concentration of the sacrificial middle film 5062 of the SiGe sacrificial layer 506 is greater than approximately 25%, and the germanium concentration of the sacrificial outer film 5061 (or the sacrificial outer film 5063) of the SiGe sacrificial layer 506 is less than approximately 25%. The sacrificial outer films 5061 and 5063 have a lower etch rate than the sacrificial middle film 5062. Therefore, the sacrificial outer films 5061 and 5063 have less lateral etching in the subsequent process, and may be referred to as sacrificial hard films.

The dummy gate stack 215 may include a dummy dielectric layer 212 and a dummy electrode layer 214 on the dummy dielectric layer 212. The dummy gate stacks 215 serve as placeholders to undergo various processes and are to be removed and replaced by the functional gate structures. At intersections of the fin-shaped structures 210 and the functional gate structures, transistors are formed. In the exemplified embodiment, with the dummy gate stacks 215 formed over the fin-shaped structures 210, the fin-shaped structures 210 are divided into channel regions 210C underlying the dummy gate stacks 215 and source/drain regions 210S/D between the channel regions 210C.

In addition, the dummy gate stacks 215 are separated from each other by a gate spacing GS in the direction D1. The gate width Wg of one of the dummy gate stacks 215 and the pitch Pgd between adjacent dummy gate stacks 215 in the direction D1 are depicted in FIG. 5A. The dummy gate stacks 215 in the channel region 210C may have a uniform gate width Wg.

Referring to FIG. 5B, in some embodiments, a gate spacer layer 218 is deposited on sidewalls of the dummy gate stack 215. The gate spacer layer 218 may be a single layer or a multi-layer. In some embodiments, the gate spacer layer 218 includes a first gate spacer 216 and a second gate spacer 217 disposed over the first gate spacer 216.

Referring to FIG. 5C, in some embodiments, the fin-shaped structures 210 in the source/drain regions 210S/D are recessed to form source/drain trenches 220. The source/drain trenches 220 expose the sidewalls 508s of the channel layers 508 and the sidewalls 506s of the sacrificial layers 506.

Referring to FIG. 5D, in some embodiments, the sacrificial layers 506 are laterally recessed to form the first recesses 523 in the fin-shaped structures 210. In some embodiments, the sacrificial layers 506 exposed in the source/drain trenches 220 are selectively etched to form the first recesses 523 while the gate spacer layer 218, the exposed portion of the fin-shaped base 210B (the substrate 202), and the channel layers 508 are substantially unetched.

In some embodiments, the sacrificial middle film 5062 (e.g., with a higher concentration of Ge) and the sacrificial outer films 5061 and 5063 (e.g., with a lower concentration of Ge) have different etch selectivities. For example, when a single etching process is performed to laterally recess the sacrificial layers 506, the etch rate of the sacrificial middle films 5062 each with a higher concentration of Ge is greater than the etch rate of the sacrificial outer films 5061 and 5063 each with a lower concentration of Ge. Thus, the first recess 523 that includes different recess amounts can be obtained by a single etching process. In some embodiments, after etching, the lateral recess amount of the sacrificial middle film 5062 is greater than the lateral recess amount of one of the sacrificial outer films 5061 and 5063. As shown in FIG. 5D, one of the first recesses 523 includes an outer recess 5231 of the sacrificial outer film 5061, a middle recess 5232 of the sacrificial middle film 5062, and an outer recess 5233 of the sacrificial outer film 5063. The middle recess 5232 in the direction D1 is greater than the outer recesses 5231 and 5233 in the direction D1.

Referring to FIG. 5E, in some embodiments, the first recesses 523 are enlarged to form the second recesses 540. In this exemplified embodiment, the outer recesses 5231 and 5233 (FIG. 5D) are further reshaped by one or more selective etching processes to form the outer recesses 5241 and 5243 with a greater vertical dimension while the middle recesses 5232 are not extended vertically and laterally. The formation of the second recesses 540 may refer to the method discussed with reference to FIGS. 3E-1-3E-4, and is not repeated herein. In some embodiments, the second recesses 540 each have a T-shaped crosssection.

Referring to FIG. 5F, in some embodiments, the inner spacers 550 are formed in the second recesses 540. For example, an inner spacer material (not shown) is deposited in the source/drain trenches 220 and fills the second recesses 540. Then, the inner spacer material is etched back to form the inner spacers 550 in the second recesses 540. In some embodiments, one of the inner spacers 550 can be divided into a main body 550M and a protrusion 550P protruding from the main body 550M. The protrusion 550P protrudes toward the sacrificial layer 506 (i.e., away from the source/drain trench 220). In some embodiments, the thickness T2 (e.g., a maximum vertical dimension) of the main body 550M of the inner spacer 550 is greater than the thickness T1 of the sacrificial layer 506. Since the protrusion 550P fills the middle recess 5232, the thickness of the protrusion 550P is substantially equal to the thickness of the sacrificial middle film 5062.

In some embodiments, as shown in FIG. 5F, the main body 550M of the inner spacer 550 has a lateral length L1 between the opposite side surfaces 550s2 and 550s1 of the main body 550M. The middle portion 550c of the inner spacer 550 has a lateral length L2 between the side surface 550s2 of the main body 550M and the side surface 550P-s of the protrusion 550P. Thus, the protrusion 550P of the inner spacer 550 increases the volume of the middle portion 550c of the inner spacer 550, thereby providing a robust inner spacer 550. As shown in FIG. 5F, the lateral length L2 is greater than the lateral length L1. In addition, in this exemplified embodiment, the side surfaces 550s2 of the inner spacers 550 are substantially flat surfaces; however, the disclosure is not limited thereto.

Next, referring to FIGS. 5G-5L, further processes which are similar to the operations in FIGS. 3G-3L can be performed. Such further processes may include, for example, deposition of base epitaxial layers 262 (shown in FIG. 5G), formation of source/drain features 264 in the source/drain trenches 220 (shown in FIG. 5H), deposition of contact etch stop layers (CESL) 266 and ILD layers 268 over the CESL 266 (shown in FIG. 5I), removal of the dummy gate stacks 215 (shown in FIG. 5J), selective removal of the sacrificial layers 506 in the channel regions to release the channel layers 508 as channel members 508 (shown in FIG. 5K), and formation of gate structures 574 over the channel regions (shown in FIG. 5L).

A gate structure 574 may include a gate dielectric layer 575, a work function adjustment layer 576 and a gate electrode layer 577. In some embodiments, the main body 550M of the inner spacer 550 is in contact with the channel member 508 and the side surface 574s of the gate structure 574. In some embodiments, the protrusion 550P is positioned between the main body 550M and the gate structure 574 (e.g., along the direction D1). In some embodiments, the protrusion 550P is vertically separated from adjacent channel members 508 (e.g., along the direction D3).

According to the semiconductor structure 200B of some embodiments, the inner spacers 550 with enlarged vertical dimensions effectively prevent the formation of cracks that typically occurred during removal of the sacrificial layers 506, thereby solving the conventional problem of metal extrusion through the cracks for forming leakage paths when a replacement gate (e.g., the gate structure 574) is formed. In addition, in some embodiments, the channel length of the semiconductor structure 200B can be increased by less etching amount on the outer sacrificial films 5061 and 5063 of the sacrificial layer 506 than the middle sacrificial film 5062 of the sacrificial layer 506. Thus, the reliability and electrical performance of the semiconductor structure can be improved.

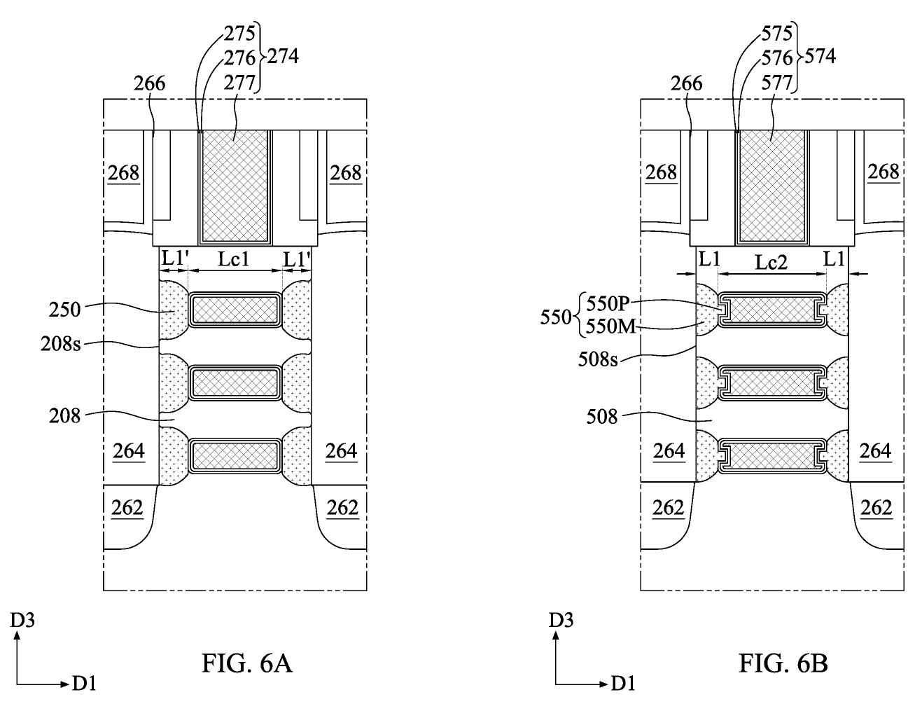

FIG. 6A illustrates a portion of the semiconductor structure in FIG. 3F, in accordance with some embodiments of the present disclosure. FIG. 6B illustrates a portion of the semiconductor structure in FIG. 5F, in accordance with some embodiments of the present disclosure.

As shown in FIG. 6A, one of the inner spacers 250 has a length L1', and a gate structure 274 that is deposited to wrap around the channel layers 208 has a channel length Lc1. That is, the channel length Lc1 is defined as the lateral length in the direction D1 between the opposite inner spacers 250. As shown in FIG. 6B, one of the main bodies 550M of the inner spacers 550 has a length L1, and a gate structure 574 that is deposited to wrap around the channel layers 508 has a channel length Lc2. That is, the channel length Lc2 is defined as a lateral length in the direction D1 between the opposite main bodies 550M of the inner spacers 250.

Referring to FIGS. 6A and 6B, in some embodiments where the sacrificial layers 206 and the sacrificial middle films 5062 include the same material, the laterally recessed amount of the sacrificial layer 206 (FIG. 3D) is substantially equal to the laterally recessed amounts of the sacrificial middle films 5062 (FIG. 5D), but greater than the laterally recessed amounts of the sacrificial outer films 5061 and 5063. Therefore, the length L1' of the inner spacers 250 is greater than the length L1 of the main bodies 550M of the inner spacers 550. After the selective removal of the sacrificial layers 506 leaves behind space 572 (FIG. 5K) between the channel layers 508, the gate structure (e.g., containing a metal gate) 574 is deposited to wrap around the channel layers 508. The less lateral recess amounts of the sacrificial outer films 5061 and 5063 lead to a larger contact area between the subsequently formed gate structure 574 and the channel layers 508, which improves the electrical performance of the semiconductor structure. In some embodiments, the channel length Lc2 of the semiconductor structure 200B (as shown in FIG. 6B) is greater than the channel length Lc1 of the semiconductor structure 200A (as shown in FIG. 6A).

FIG. 7 is a fragmentary cross-sectional view of a semiconductor structure at an intermediate stage, in accordance with some other embodiments of the present disclosure. The structure of FIG. 7 may be formed by a method similar to the operations in FIGS. 5A-5L. In some embodiments, when an inner spacer material is deposited in the source/drain trenches 220 and the second recesses 540 (FIG. 5F), for example, by ALD, the inner spacer material may not completely fill the second recesses 540, and the semiconductor structure may include air voids 560 (also can be referred to as air seams or air pockets) in some or all of the inner spacers 550 after the source/drain features 264 are subsequently formed in the source/drain trenches 220. The air voids 560 are positioned between the source/drain features 264 and the inner spacers 550.

In some embodiments, each of the inner spacers 550 includes a main body 550M and a protrusion 550P protruding toward the gate structure 574. Additionally, the protrusion 550P and the air void 560 may be positioned relative to the middle portion 550c of the inner spacer 550. In some embodiments, the main body 550M of one of the inner spacers 550 has opposite side surfaces 550s2 and 550s1. The side surface 550s2 may include a recessed portion 550r positioned in the middle portion 550c of the inner spacer 550. The remaining portion of the side surface 550s2 of the inner spacer 550 may be substantially flush with the sidewalls 508s of the channel layers 508. The recessed portion 550r of the side surface 550s2 of the inner spacer 550 and the source/drain feature 264 adjacent to the inner spacer 550 define an air void 560. As shown in FIG. 7, one of the air voids 560 has a vertical dimension of Da. Those air voids 560 may have substantially the same dimension or different dimensions.

In some embodiments, although the main body 550M has the recessed portion 550r, the volume of the middle portion 550c of the inner spacer 550 can be increased with the formation of the protrusion 550P.

Specifically, as shown in FIG. 7, the main body 550M of the inner spacer 550 has a lateral length L1 between the side surface 550s2 and the side surface 550s1 in the direction D1. The middle portion 550c of the inner spacer 550 has a lateral length L2 between the side surface 550P-s of the protrusion 550P and the recessed portion 550r of the side surface 550s2 of the main body 550M in the direction D1. In some embodiments, the thickness Tp of the protrusion 550P is substantially equal to or greater than the dimension Da of the air void 560. In some embodiments, the lateral length L1 is substantially the same as the lateral length L2. In some embodiments, the lateral length L2 is greater than the lateral length L1. According to the embodiments, the formation of the protrusion 550P compensates the volume loss of the inner spacer 550 due to formation of the air void 560. Thus, the protrusion 550P of the inner spacer 550 that increases the volume of the middle portion 550c of the inner spacer 550 provides a robust inner spacer 550.

According to the structures in FIGS. 5L and 7, the inner spacers 550 each have a T-shaped cross section. After the gate structure 574 is deposited to wrap around the channel layers 508, the T-shaped inner spacers 550 lead to a larger contact area between the gate structure 574 and the channel layers 508, as described above. In addition, when the sacrificial layers 506 are removed (e.g., FIG. 5K), the inner spacers 550 each have an enlarged vertical dimension effectively prevent the channel layers 508 from being etched through over the tops of the inner spacers 550 and/or beneath the bottoms of the inner spacers 550. In addition, in some embodiments where the semiconductor structure includes one or more air voids 560 (e.g., FIG. 7), which may be unintentionally formed by deposition of inner spacer material, the protrusions 550M of the inner spacers 550 thicken the middle portions 550c of the inner spacers 550 and prevent the middle portions 550c from being etched through (e.g., forming undesirable cracks) during removal of the sacrificial layers 506. Accordingly, the reliability and electrical performance of the semiconductor structures in FIGS. 5L and 7 can be effectively improved.

According to some other embodiments of the present disclosure, the inner spacers with protrusions can be fabricated by another method.

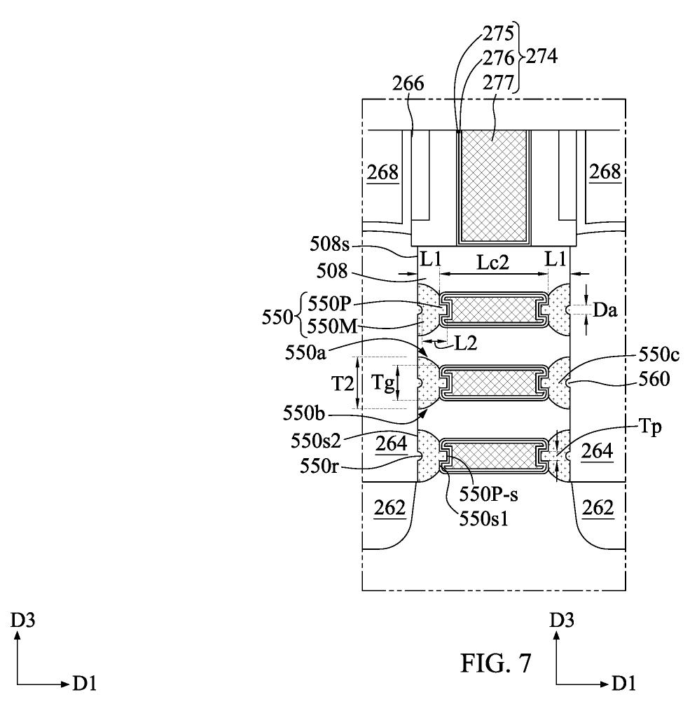

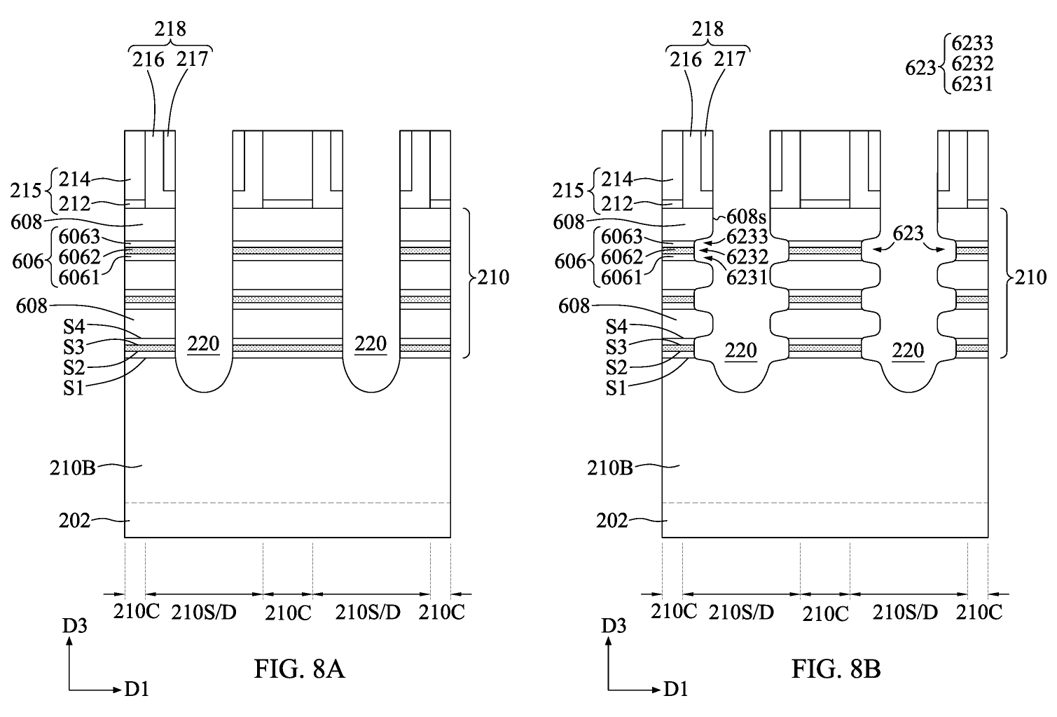

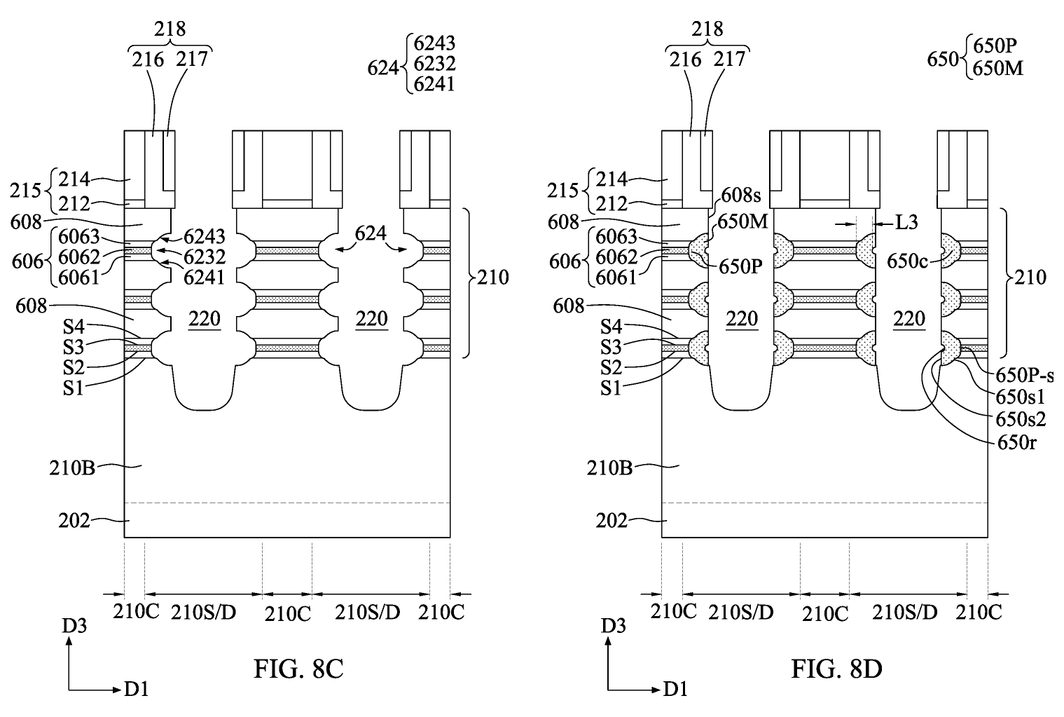

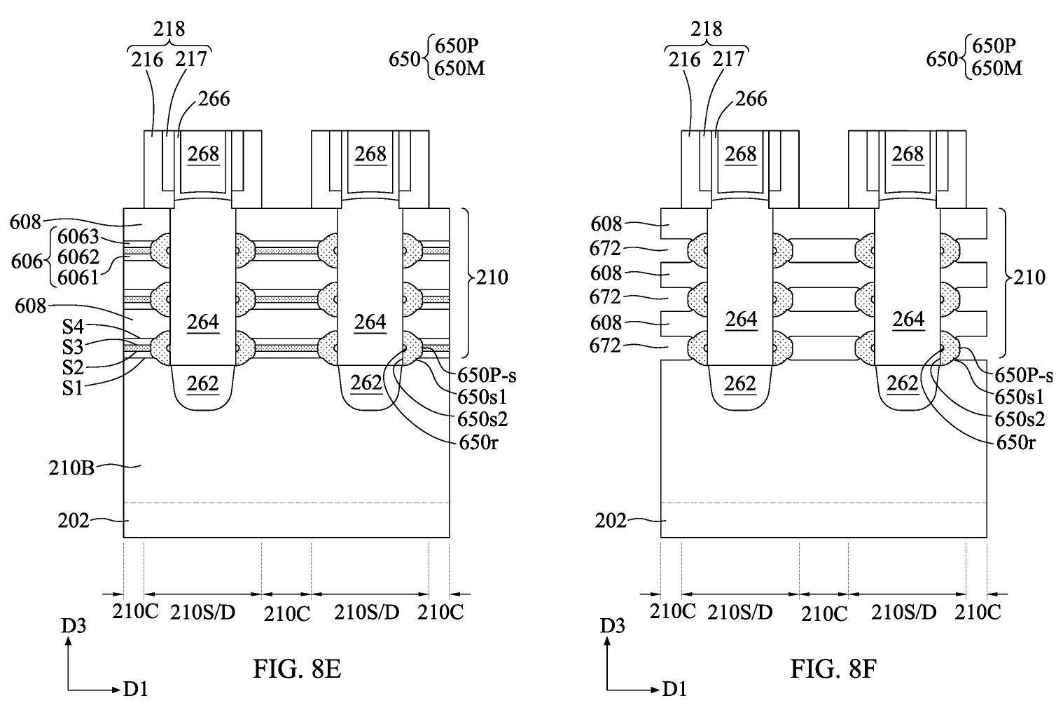

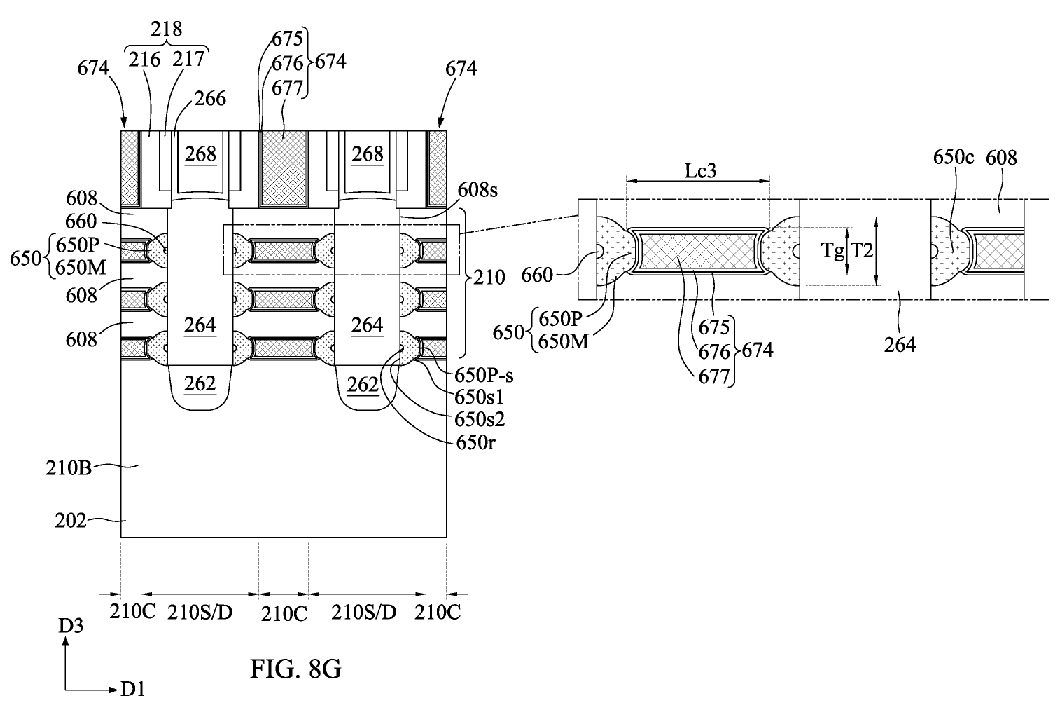

FIGS. 8A-8G are fragmentary cross-sectional views of manufacturing a semiconductor structure at various intermediate stages, in accordance with some embodiments of the present disclosure. The features/components in FIGS. 8A-8G that are similar or identical to the features/components in FIGS. 5C-5L are designated with similar or the same reference numbers. Details of the arrangement, materials and manufacturing methods of those similar or identical features/components shown in FIGS. 8A-8G are essentially the same as those discussed with reference to FIGS. 5C-5L and 3C-3L, and are not repeated herein.

Referring to FIGS. 2 and 8A, in some embodiments, multiple fin-shaped structures 210 protruding from the substrate 202 and multiple dummy gate stacks 215 positioned across the fin-shaped structures 210 are provided. Each of the fin-shaped structures 210 includes alternating layers atop a fin-shaped base 210B. The formation of the fin-shaped structures 210 may include depositing a lamination (not shown) on the substrate 202 through an epitaxial growth process. The lamination and the top portion of the substrate 202 are patterned to form multiple stacks. Each stack includes a fin-shaped structure 210. In addition, each stack includes sacrificial layers 606 interleaved with channel layers 608.

In addition, the dummy gate stack 215 may include a dummy dielectric layer 212 and a dummy electrode layer 214 on the dummy dielectric layer 212. With the dummy gate stack 215 formed over the fin-shaped structures 210, the fin-shaped structures 210 are divided into channel regions 210C underlying the dummy gate stacks 215 and source/drain regions 210S/D between the channel regions 210C. Then, in some embodiments, a gate spacer layer 218 (including a first gate spacer 216 and a second gate spacer 217) is deposited on the sidewalls of the dummy gate stack 215. The bottom portion of the gate spacer layer 218 and the fin-shaped structures 210 in the source/drain regions 210S/D are then removed to form the source/drain trenches 220.

In this exemplified embodiment, each of the sacrificial layers 606 includes a sacrificial middle film 6062 positioned between two sacrificial outer films 6061 and 6063. The sacrificial middle film 6062 and the sacrificial outer films 6061 and 6063 exhibit different etch rates. In some embodiments, the sacrificial layers 606 include silicon germanium (SiGe), and the germanium concentration of the sacrificial middle film 6062 is greater than the average germanium concentration in either of the sacrificial outer films 6061 and 6063. In some embodiments, the sacrificial outer films 6061 and 6063 each have a germanium concentration gradient that decreases from the sacrificial middle film 6062 to the channel layers 608.

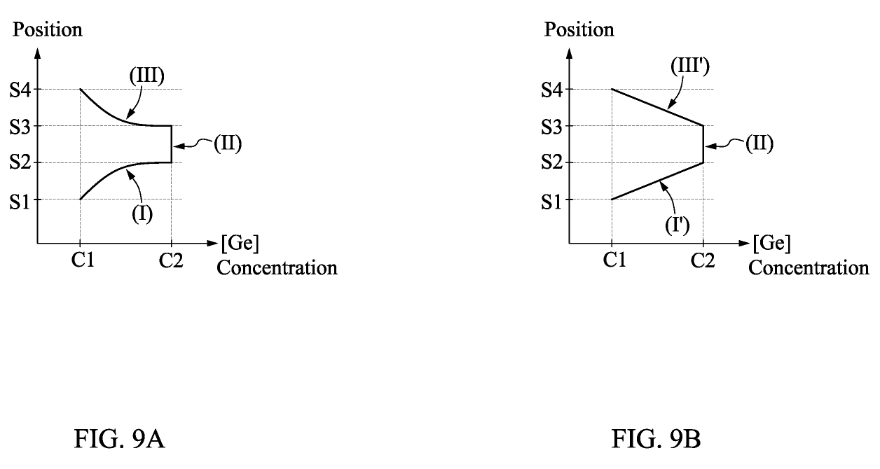

FIG. 9A is a graph depicting a distribution of germanium concentration across the sacrificial layer 606, in accordance with some embodiments of the present disclosure. In some embodiments, the sacrificial middle film 6062 of the sacrificial layer 606 has a uniform germanium concentration C2, while the sacrificial outer films 6061 and 6063 each have a germanium concentration decreasing with increasing distance from the sacrificial middle film 6062.

Specifically, as shown in FIGS. 8A and 9A, the sacrificial outer film 6061 has a lower surface S1 in contact with the channel layer 608, and an upper surface S2 in contact with the sacrificial middle film 6062. Curve (I) represents the distribution of germanium concentration in the sacrificial outer film 6061. The germanium concentration of the sacrificial outer film 6061 varies from the maximal value C2 at the upper surface S2 to the minimal value C1 at the lower surface S1. Curve (II) represents the distribution of germanium concentration in the sacrificial middle film 6062, which is uniform at the maximal value C2. In addition, the sacrificial outer film 6063 has a lower surface S3 in contact with the sacrificial middle film 6062, and an upper surface S4 in contact with the channel layer 608. Curve (III) represents the distribution of germanium concentration in the sacrificial outer film 6063. The germanium concentration of the sacrificial outer film 6061 varies from the maximal value C2 at the lower surface S3 to the minimal value C1 at the upper surface S4.

FIG. 9B is another graph depicting a distribution of germanium concentration across the sacrificial layer 606, in accordance with some embodiments of the present disclosure. Distributions of germanium concentration in FIGS. 9A and 9B have a similar tendency, except that the curves (I) and (III) in FIG. 9A exponentially decrease with the distances from the sacrificial middle film 6062, and the curves (I') and (III') in FIG. 9B linearly decrease with the distances from the sacrificial middle film 6062. Accordingly, in this exemplified embodiment, the sacrificial layer 606 has the lowest germanium concentration at the interfaces (i.e., the surfaces S1 and S4) between the sacrificial layer 606 and the channel layers 608. In some embodiments, the minimal value C1 of the germanium concentration may be substantially zero.

For a GAA nanosheet transistor in which the channel layers 608 are silicon (Si) layers and the sacrificial layers 606 are silicon germanium (SiGe) layers, Ge diffuses from the SiGe layers into the Si channel layers due to the high thermal budget of the subsequent processes (e.g., shallow trench isolation (STI) oxide anneal, S/D epitaxy growth, etc.). Unwanted germanium diffusion can cause a series of issues, including, for example, shifting the gate threshold voltage and poor SiGe indentation profiles for the inner spacer formation operations. Therefore, according to this embodiment, the distribution of germanium concentration in the sacrificial layer 606, which includes the highest germanium concentration in the middle portion and a decreasing germanium concentration with increasing distance from the middle portion, effectively reduces germanium diffusion, thereby improving the reliability and electrical performance of the semiconductor structure.

Next, referring to FIG. 8B, in some embodiments, the sacrificial layers 606 are laterally recessed to form the first recesses 623 in the fin-shaped structures 210. In some embodiments, the etch rate of the sacrificial middle film 6062, which has a higher concentration of Ge, is greater than the etch rate of the sacrificial outer films 6061 and 6063. In addition, the lateral recess amount of the sacrificial middle film 6062 is greater than the lateral recess amount of the sacrificial outer films 6061 and 6063. As shown in FIG. 8B, one of the first recesses 623 includes an outer recess 6231 of the sacrificial outer film 6061, a middle recess 6232 of the sacrificial middle film 6062 and an outer recess 6233 of the sacrificial outer film 6063. Since the sacrificial outer films 6061 and 6063 each include a decreasing germanium concentration with increasing distance from the middle portion, the sacrificial outer films 6061 and 6063 have curved surfaces that define the outer recesses 6231 and 6233 after etching. In some embodiments, after a single etching process is performed, the sacrificial outer films 6061 and 6063 exhibit curved surfaces.

Next, referring to FIG. 8C, in some embodiments, the first recesses 623 are enlarged to form the second recesses 624. In this exemplified embodiment, the outer recesses 6231 and 6233 (FIG. 8B) are further reshaped to form the outer recesses 6241 and 6243, each having a greater vertical dimension. The operation for forming the second recesses 624 may include cyclical oxidation and removal processes performed on the channel layers 608 to enlarge the first recesses 623 while the gate spacer layer 218 and the sacrificial middle films 6062 are substantially unetched. The formation of the second recesses 624 may refer to the method discussed with reference to FIGS. 3E-1 - 3E-4, and is not repeated herein. In some embodiments, the removal processes may include one or more dry etching processes and one or more wet etching processes that are continuously repeated until the second recesses 624 with the desired dimensions are formed.

Referring to FIG. 8D, in some embodiments, the inner spacers 650 are formed in the second recesses 624. The inner spacer 650 includes a main body 650M and a protrusion 650P protruding toward the sacrificial layer 606. In addition, the protrusion 650P protrudes from the side surface 650s1 of the main body 650M. In some embodiments, the side surface 650P-s of the protrusion 650P of one of the inner spacers 650 is convex (i.e., bending outward toward the respective sacrificial layers 606) in the cross-sectional view.

The inner spacers 650 may be formed by CVD, ALD, or any suitable method. In one embodiment, the inner spacers 650 are formed using a highly conformal deposition process such as ALD to form several spacer films each having a uniform thickness along the sidewalls of the second recesses 624. However, the second recesses 624 may not be fully filled by the inner spacer material using ALD. After the source/drain feature 264 are formed in the subsequent process, as shown in FIG. 8E, an air void 660 (also can be referred to as air seam, or air pocket) may be formed in the second recess 624 and positioned between the inner spacer 650 and the source/drain feature 264.

In addition, in some embodiments, the protrusion 650P and the air void 660 formed subsequently (e.g., in FIG. 8E) may be positioned relative to the middle portion 650c of the inner spacer 650. Specifically, the main body 650M of the inner spacer 650 includes side surfaces 650s2 and 650s1. The side surface 650s2 includes a recessed portion 650r positioned in a middle portion 650c of the inner spacer 650. The remaining portion of the side surface 650s2 of the inner spacer 650 is substantially flush with the sidewalls 608s of the channel layers 608. Although the side surface 650s2 of the main body 650M includes the recessed portion 650r, the volume of the middle portion 650c of the inner spacer 650 can be increased with the formation of the protrusion 650P. As shown in FIG. 8D, the middle portion 650c between the side surface 650P-s of the protrusion 650P and the recessed portion 650r of the side surface 650s2 of main body 650M has a lateral length L3 in the direction D1. With the protrusion 650P, the volume of the middle portion 650c of the inner spacer 650 can be increased, thereby providing a robust inner spacer 650.

Next, referring to FIGS. 8E-8G, in some embodiments, further processes that are similar to the operations in FIGS. 5G-5L may be performed. Such further processes may include, for example, deposition of the base epitaxial layers 262, formation of the source/drain features 264 in the source/drain trenches 220, deposition of the contact etch stop layers (CESL) 266 and the ILD layers 268 over the CESL 266, and removal of the dummy gate stacks 215 (shown in FIG. 8E); selective removal of the sacrificial layers 606 in the channel regions to release the channel layers 608 as channel members 608 (shown in FIG. 8F), and formation of the gate structures 674 over the channel regions (shown in FIG. 8G). A gate structure 674 may include a gate dielectric layer 675, a work function adjustment layer 676 and a gate electrode layer 677. In some embodiments, the protrusion 650P of one of the inner spacers 650 has a convex side surface 650P-s in contact with the gate structure 674 in the cross-sectional view. During formation of the gate structures 674 to wrap around the channel regions, the convex side surfaces 650P-s of the protrusions 650P may facilitate the conformal deposition of the gate structures 674 on the protrusions 650P to wrap around the channel regions.

According to the semiconductor structure 200C of some embodiments, the inner spacers 650 with enlarged vertical dimensions effectively prevent the formation of cracks that typically occur during removal of the sacrificial layers 606, thereby solving the conventional problem of leakage paths by metal extrusion through the cracks when a replacement gate (e.g., the gate structure 674) is formed. In addition, in some embodiments, the channel length Lc3 of the semiconductor structure 200C can be increased by less etching amount on the outer sacrificial films 6061 and 6063 of the sacrificial layer 606 than the middle sacrificial film 6062 of the sacrificial layer 606. In addition, according to the semiconductor structure 200C of some embodiments, the protrusions 650M of the inner spacers 650 thicken the middle portions 650c of the inner spacers 650 and prevent the inner spacers from being etched through (e.g., forming undesirable cracks) during removal of the sacrificial layers 606. In addition, according to the method for forming the semiconductor structure 200C of some embodiments, the sacrificial layers 606 that have a germanium concentration gradient decreasing from the middle portions of the sacrificial layers 606 to the channel layers 608 (FIG. 8A) effectively reduce germanium diffusion in the subsequent processes with high thermal budget.

Although not intended to be limiting, one or more embodiments of the present disclosure provide many benefits to a semiconductor structure and the formation thereof. For example, embodiments of the present disclosure provide inner spacers interleaving the channel members, and the inner spacers have enlarged dimensions to prevent the formation of leakage paths between the metal gate and the source/drain features. In addition, in some embodiments, robust inner spacers can be provided by forming protrusions in the middle portions of the inner spacers. In some embodiments, the inner spacers with protrusions compensate the volume loss when one or more voids are formed between the inner spacers and the source/drain features. In addition, in some embodiments, a larger contact area between the gate structure and the channel layers can be achieved by forming the inner spacers with protrusions, which boosts the performance of the semiconductor structure (e.g., transistor). Accordingly, the reliability and electrical performance of the semiconductor structure of the embodiments are greatly improved.

In one exemplary aspect, the present disclosure is directed to a method. The method includes alternately stacking channel layers and sacrificial layers on a substrate in a vertical direction to form a semiconductor stack, patterning the semiconductor stack to form a fin-shaped structure protruding from the substrate, forming a source/drain trench in the fin-shaped structure, laterally recessing the sacrificial layers in the fin-shaped structure to form first recesses, and enlarging the first recesses to form second recesses. The method further includes forming a contact etch stop layer over the source/drain feature, and forming an interlayer dielectric (ILD) layer over the CESL. The first recesses at opposite ends of one of the sacrificial layers are separated from each other along a direction. The thickness of the CESL along the direction is less than the thickness of the ILD layer. One of the second recesses has a vertical dimension greater than a thickness of the sacrificial layer after enlarging the first recesses. The method further includes forming inner spacers in the second recesses, and forming a source/drain feature in the source/drain trench.

In some embodiments, an anisotropical etching is performed to enlarge the vertical dimension of the first recesses. In some embodiments, the first recesses expose opposite ends of the channel layers, and forming the second recesses includes partially etching exposed portions of the channel layers to form the second recesses. In some embodiments, one of the sacrificial layers includes a sacrificial middle film disposed between two sacrificial outer films, and a lateral recess amount of the sacrificial middle film is greater than a lateral recess amount of one of the sacrificial outer films when laterally recessing the sacrificial layers. In some embodiments, the sacrificial layers are laterally recessed by etching, and an etch rate of the sacrificial middle film is higher than an etch rate of the sacrificial outer films. In some embodiments, the sacrificial middle film and the sacrificial outer films of the sacrificial layers are laterally recessed using a single etching process, thereby forming the first recesses. In some embodiments, a germanium concentration of the sacrificial middle film is greater than a germanium concentration of the sacrificial outer films. In some embodiments, one of the sacrificial outer films has a germanium concentration gradient decreasing from the sacrificial middle film to the channel layer adjacent to the sacrificial outer film.

In another exemplary aspect, the present disclosure is directed to a method. The method includes forming a fin-shaped structure including a stack atop a base, the stack including channel layers interleaved with sacrificial layers. The base protrudes from a substrate, and the fin-shaped structure includes a channel region and a source/drain region. The method further includes forming a dummy gate stack over the channel region of the fin-shaped structure, depositing a gate spacer layer over the dummy gate stack, and forming a source/drain trench by recessing the source/drain region of the fin-shaped structure. The source/drain trench exposes sidewalls of the channel layers and the sacrificial layers. The method further includes selectively and partially recessing the sacrificial layers to form first recesses, and enlarging the first recesses to form second recesses. One of the second recesses has a vertical dimension greater than a thickness of the sacrificial layer. The method further includes forming inner spacers in the second recesses, and forming a source/drain feature in the source/drain trench, wherein a void is formed between the source/drain feature and one of the inner spacers. The method further includes forming a contact etch stop layer over the source/drain feature, and forming an interlayer dielectric (ILD) layer over the CESL, wherein the dielectric constant of the CESL is greater than the dielectric constant of the ILD layer.

In some embodiments, the sacrificial layers are partially recessed to expose opposite end portions of the channel layers to form the first recesses, and the first recesses are enlarged by partially removing the exposed end portions of the channel layers through directional oxidation and selective etch to form the second recesses. In some embodiments, the void is positioned relative to a middle portion of the one of the inner spacers. In some embodiments, one of the sacrificial layers includes a sacrificial middle film disposed between two sacrificial outer films. A lateral recess amount of the sacrificial middle film is greater than a lateral recess amount of one of the two sacrificial outer films when the sacrificial layers are partially recessed by a single etching process to form the first recesses. In some embodiments, one of the sacrificial layers includes a middle portion formed between outer portions, and a germanium concentration of the middle portion is greater than a germanium concentration of the outer portions.

In yet another exemplary aspect, the present disclosure is directed to a semiconductor structure. The semiconductor structure includes channel members suspended above a substrate, inner spacers interleaving the channel members, a gate structure wrapping around the channel members, a source/drain feature abutting the channel members, a contact etch stop layer over the source/drain feature, and an interlayer dielectric (ILD) layer over the CESL. The source/drain feature is partially embedded in the substrate and beneath the ILD layer. The inner spacers extend into end portions of the channel members that are adjacent to the inner spacers. One of the inner spacers has a vertical dimension greater than the channel member.

In some embodiments, one of the inner spacers has a vertical thickness greater than a thickness of a portion of the gate structure between two adjacent channel members. In some embodiments, one of the inner spacers includes a main body disposed against a portion of a lateral side surface of the gate structure, and a protrusion protruding from the main body and extending in a direction away from the source/drain feature. In some embodiments, the protrusion is vertically separated from adjacent channel members, and the protrusion is in contact with a portion of the gate structure between the channel members. In some embodiments, a side surface of the main body has a recessed portion, and a void is formed between the recessed portion of the side surface of the main body and the source/drain feature. In some embodiments, the protrusion includes a convex surface in contact with the gate structure between the channel members. In some embodiments, one of a top surface and a bottom surface of one of the inner spacers includes a first part adjacent to the gate structure and a second part adjacent to the source/drain feature, and the first part is more slanted relative to a plane that the channel members extend along than the second part.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
alternately stacking channel layers and sacrificial layers on a substrate in a vertical direction to form a semiconductor stack;
patterning the semiconductor stack to form a fin-shaped structure protruding from the substrate;
forming a source/drain trench in the fin-shaped structure;
laterally recessing the sacrificial layers in the fin-shaped structure to form first recesses, wherein one of the sacrificial layers comprises a middle portion and an outer portion between the middle portion and an adjacent one of the channel layers, and a lateral recess amount of the middle portion is greater than a lateral recess amount of the outer portion;
removing portions of the channel layers adjacent to the first recesses to enlarge the first recesses and form second recesses;
forming inner spacers in the second recesses;
forming a source/drain feature in the source/drain trench;
forming a contact etch stop layer (CESL) over the source/drain feature; and
forming an interlayer dielectric (ILD) layer over the CESL.

2. The method of claim 1, wherein removing the portions of the channel layers adjacent to the first recesses is performed by an anisotropic etching process having a greater etching rate along the vertical direction than along a horizontal direction perpendicular to the vertical direction.

3. The method of claim 1, wherein a germanium concentration of the middle portion is greater than a germanium concentration of the outer portion.

4. The method of claim 1, wherein a germanium concentration of the outer portion decreases non-linearly with increasing distance from the middle portion.

5. The method of claim 1, wherein the middle portion and the outer portion of one of the sacrificial layers are laterally recessed using a single etching process, thereby forming the first recesses.

6. The method of claim 1, wherein one of the second recesses has a vertical dimension greater than a thickness of the sacrificial layer.

7. The method of claim 1, wherein removing the portions of the channel layers is performed while the sacrificial layers remain substantially unetched.

8. The method of claim 1, wherein an air void is formed between the inner spacers and the source/drain feature after forming the source/drain feature in the source/drain trench.

9. A method for forming a semiconductor structure, comprising:
forming a fin-shaped structure including a stack atop a base, the stack comprising channel layers interleaved with sacrificial layers, the base protruding from a substrate, the fin-shaped structure comprising a channel region and a source/drain region;
forming a dummy gate stack over the channel region of the fin-shaped structure;
depositing a gate spacer layer over the dummy gate stack;
forming a source/drain trench by recessing the source/drain region of the fin-shaped structure, wherein the source/drain trench exposes sidewalls of the channel layers and the sacrificial layers;
selectively and partially recessing the sacrificial layers to form first recesses, wherein the first recesses expose opposite end portions of the channel layers;
selectively etching the opposite end portions of the channel layers exposed by the first recesses to thin the opposite end portions and to expand the first recesses into second recesses;
forming inner spacers in the second recesses;
forming a source/drain feature in the source/drain trench;
forming a contact etch stop layer (CESL) over the source/drain feature; and
forming an interlayer dielectric (ILD) layer over the CESL.

10. The method of claim 9, wherein after forming the second recesses, one of the channel layers has a first thickness at the opposite end portions and a second thickness at a middle portion between the opposite end portions, the first thickness being less than the second thickness.

11. The method of claim 9, wherein selectively etching the opposite end portions of the channel layers comprises an oxidation step of oxidizing the opposite end portions to form oxide portions and a removal step of removing the oxide portions.

12. The method of claim 11, wherein the oxidation step and the removal step are performed repeatedly in a cyclic manner.

13. The method of claim 9, wherein selectively etching the opposite end portions of the channel layers is performed while the gate spacer layer and the sacrificial layers remain substantially unetched.

14. The method of claim 9, wherein one of the inner spacers has a top surface positioned at a level higher than a top surface of an adjacent one of the sacrificial layers, and a bottom surface positioned at a level lower than a bottom surface of the adjacent one of the sacrificial layers.

15. The method of claim 9, wherein a void is formed between the source/drain feature and one of the inner spacers.

16. The method of claim 9, wherein a dielectric constant of the CESL is greater than a dielectric constant of the ILD layer.

17. A semiconductor structure, comprising:
channel members suspended above a substrate;
inner spacers interleaving the channel members;
a gate structure wrapping around the channel members;
a source/drain feature abutting the channel members, wherein one of the inner spacers has a vertical dimension greater than a vertical dimension of an adjacent gate portion of the gate structure between the channel members, and a protrusion of the one inner spacer protrudes toward a middle portion of the adjacent gate portion;
a contact etch stop layer (CESL) over the source/drain feature; and
an interlayer dielectric (ILD) layer over the CESL.

18. The semiconductor structure of claim 17, wherein the one of the inner spacers comprises a main body between the source/drain feature and a lateral side surface of the adjacent gate portion, and the protrusion disposed between the main body and the adjacent gate portion.

19. The semiconductor structure of claim 17, wherein a void is formed between one of the inner spacers and the source/drain feature.

20. The semiconductor structure of claim 17, wherein the source/drain feature is partially embedded in the substrate and beneath the ILD layer.
